(19) United States
(12) Patent Application Publication
(10) Pub. No.: US 2025/0087558 A1
(43) Pub. Date: Mar. 13, 2025

(54) DIRECT POWER MODULE COOLING

(71) Applicant: PC KRAUSE AND ASSOCIATES, INC., West Lafayette, IN (US)

(72) Inventors: Matthew Clark, West Lafayette, IN (US); Kevin McCarthy, West Lafayette, IN (US); Nicholas Benavides, West Lafayette, IN (US)

(21) Appl. No.: 18/827,549

(22) Filed: Sep. 6, 2024

Related U.S. Application Data
(60) Provisional application No. 63/536,959, filed on Sep. 7, 2023.

(51) Int. Cl. H01L 23/473; H01L 21/50; H01L 23/495; H01L 25/065; H02G 5/10

(52) U.S. Cl. CPC H01L 23/4735; H01L 21/50; H01L 23/49568; H01L 23/49575; H02G 5/10; H01L 25/0655

(57) ABSTRACT

A power module assembly includes a frame assembly and a bus bar assembly. The frame assembly includes an upper frame body and a lower frame body coupled to the upper frame body, at least one of the upper and lower frame bodies including at least one jet orifice formed therethrough, the jet orifice configured to receive coolant at a first end and discharge the coolant at a second end, the upper and lower frame bodies at least partially defining a chamber therebetween. The bus bar assembly is arranged in the chamber and includes a bus bar arranged adjacent to the second end of the jet orifice. The jet orifice is configured to discharge the coolant directly onto the bus bar so as to reduce an operating temperature of the bus bar.

### CROSS-REFERENCE TO RELATED APPLICATIONS

This nonprovisional application claims the benefit and priority, under 35 U.S.C. § 119(e) and any other applicable laws or statues, to U.S. Provisional Patent Application No. 63/536,959 filed on Sep. 7, 2023, the entire disclosure of which is hereby expressly incorporated herein by reference.

### BACKGROUND

The present disclosure relates to electronic systems, in particular electronic systems having more power dense solutions and improving the operation of such systems.

### SUMMARY

According to a first aspect of the present disclosure, a power module assembly includes a frame assembly and a bus bar assembly. The frame assembly includes an upper frame body and a lower frame body coupled to the upper frame body, at least one of the upper and lower frame bodies including at least one first jet orifice formed therethrough. The at least one first jet orifice is configured to receive coolant at a first end and discharge the coolant at a second end opposite the first end. The upper and lower frame bodies at least partially define a chamber therebetween. The bus bar assembly is arranged in the chamber and includes a first bus bar arranged adjacent to the second end of the at least one first jet orifice. The at least one first jet orifice is configured to discharge the coolant directly onto the first bus bar so as to reduce an operating temperature of the first bus bar.

According to a further aspect of the present disclosure, a power module assembly includes a frame assembly and a bus bar assembly. The frame assembly includes a first frame body including a first jet orifice formed therethrough and a second frame body coupled to the first frame body. The bus bar assembly is arranged at least partially within the second frame body and includes a first bus bar arranged adjacent to an outlet of the first jet orifice. The first jet orifice is configured to discharge coolant from the outlet directly onto the first bus bar so as to reduce an operating temperature of the first bus bar.

According to a further aspect of the present disclosure, a method includes coupling a lower frame body to an upper frame body to form a frame assembly, the upper and lower frame bodies at least partially defining a chamber therebetween, forming at least one first jet orifice through at least one of the upper and lower frame bodies, directing coolant to a first end of the at least one first jet orifice, arranging a bus bar assembly in the chamber, the bus bar assembly including a first bus bar arranged adjacent to a second end of the at least one first jet orifice opposite the first end, and discharging the coolant at the second end of the at least one first jet orifice directly onto the first bus bar so as to reduce an operating temperature of the first bus bar.

Additional features of the present disclosure will become apparent to those skilled in the art upon consideration of illustrative embodiments exemplifying the best mode of carrying out the disclosure as presently perceived.

### BRIEF DESCRIPTIONS OF THE DRAWINGS

The detailed description particularly refers to the accompanying figures in which:

FIG. 1 is an exploded view of a power module assembly according to the present disclosure, showing that the power module includes integrated fluid manifolds each formed at least in part by plenums and lids surrounding a frame body, and showing that the fluid, which may be a coolant, is configured to be directed toward dies of a bus bar assembly of the power module assembly via jet impingement orifices;

FIG. 2 is a cross-section view of the power module assembly of FIG. 1, showing the frame body sandwiched between opposing plenums and lids, and the bus bar assembly arranged within the frame body, and showing fluid paths of the coolant extending from an inlet to an outlet on top and bottom sides of the bus bar assembly;

FIG. 3A is a top perspective view of the frame body of the power module assembly of FIG. 1, showing that the power module assembly includes a bus bar assembly arranged in an opening formed in the frame body, showing that the bus bar assembly can include bare dies formed on bus bars of the bus bar assembly that are exposed to the coolant and that are attached to bus bars of the bus bar assembly extending through and out of the frame body, and showing that the bus bars can extend through the sides of the frame body via openings and that molded insulating flanges seal the bus bars in the openings to form two DC input tabs and an output tab;

FIG. 3B is a bottom perspective view of the frame body of FIG. 3A, showing that the bus bars may include at least one extended surface formed on a bottom surface of the bus bar, and showing the extended surface may be formed as pin fins;

FIG. 4 is a top perspective view of the frame body of FIG. 3A, showing that the bus bar assembly can include separate copper blocks arranged on the bare dies of the bus bar assembly, and showing that the copper blocks can include machined pin fins for increased heat transfer area;

FIG. 5 is a top perspective view of the frame body of FIG. 3A, showing that the bus bar assembly can include an elongated copper block arranged on and extending over all of the bare dies of the bus bar assembly, and showing that the elongated copper block can include machined pin fins for increased heat transfer area;

FIG. 6 is a top perspective view of the frame body of FIG. 3A, showing that the bus bars extend through the sides of the frame body via openings, and that the bus bars can be sealed in the openings via extended insulating flanges that extend across a majority of the longitudinal sides of the frame body;

FIG. 7 is a perspective view of an arrangement of multiple power module assemblies of FIG. 1 in which multiple power modules can be supplied with coolant in parallel in a planar, horizontal configuration;

FIG. 8 is a perspective view of an arrangement of multiple power module assemblies of FIG. 1 in which multiple power modules can be supplied with coolant in parallel in a vertical configuration;

FIG. 9 is a perspective view of a power module assembly according to a further aspect of the present disclosure, showing that the power module can include fluid manifolds integrated into single frame components as opposed to the multiple layers of plenums, lids, and a frame body as shown in FIG. 1;

FIG. 10 is a top view of the power module assembly of FIG. 9, showing a fluid inlet plenum and a fluid outlet of a top frame body of the power module assembly;

FIG. 11 is a top perspective view of a bottom frame body of the power module assembly of FIG. 9, showing a bus bar assembly arranged within an opening formed in the bottom frame body of the power module assembly, the bus bar assembly including a printed circuit board, dies formed on bus bars of the bus bar assembly, MOSFET dies formed on a bus bar of the bus bar assembly, ribbon bonds, and two DC input tabs and an output tab;

FIG. 12A is a top perspective view of the bus bar assembly of the power module assembly of FIG. 9, showing the printed circuit board, dies, MOSFET dies, ribbon bonds, and the DC input tabs and the output tab, and showing insulating flanges may be formed on the bus bars to seal the bus bars within openings formed between the top and bottom frame bodies;

FIG. 12B is a bottom perspective view of the bus bar assembly of FIG. 12A, showing that the bus bars may include at least one extended surface formed on a bottom surface of the bus bar, and showing the extended surface may be formed as pin fins;

FIG. 13A is a bottom perspective view of the top frame body of the power module assembly of FIG. 9, showing that the top frame body includes the fluid inlet plenum, the fluid outlet, and bus bar supports and notches;

FIG. 13B is a top perspective view of the bottom frame body of the power module assembly of FIG. 9, showing that the bottom frame body includes a jet orifice area in the opening formed by the frame body, a bottom fluid outlet, and bus bar key slots and notches;

FIG. 14 is a cross-section view of the power module assembly of FIG. 9, showing the bus bar assembly arranged between the top and bottom frame bodies, and showing fluid paths of the coolant extending from an inlet to an outlet on top and bottom sides of the bus bar assembly;

FIG. 15A is a top perspective view of an alternative bus bar assembly of the power module assembly of FIG. 9, showing that one of the DC input tabs and associated bus bar is vertically offset from the other DC input tab and bus bar, and showing that the other DC input bus bar and the output bus bar include extended wings and extended surfaces such as pin fins for additional heat spreading;

FIG. 15B is a bottom perspective view of the bus bar assembly of FIG. 15A, showing that the bus bars may include additional extended surfaces formed as pin fins on the bottom surface;

FIG. 16 is a perspective view of a power module assembly according to a further aspect of the present disclosure, showing that top and bottom frame bodies that together form a frame assembly can be formed from non-conductive material, thus eliminating the need for insulation between the bus bars and the frame body, via, for example, the insulating flanges of other embodiments described herein;

FIG. 17 is a top perspective view of the bottom frame body of the power module assembly of FIG. 16, showing a bus bar assembly arranged on the bottom frame body and aligned thereto via corresponding alignment holes and pins;

FIG. 18 is an exploded view of the power module assembly of FIG. 16, showing the bus bar assembly arranged between the top and bottom frame bodies, and showing the jet orifices formed in the top and bottom frame bodies;

FIG. 19A is a perspective view of a power module assembly according to a further aspect of the present disclosure, showing that the power module includes a frame assembly including a main frame body, top and bottom lids enclosing the main frame body, and a bus bar assembly arranged in the main frame body, the main frame body being formed from non-conductive material to eliminate the usage of insulation between the bus bars and the frame body, and showing that each bus bar includes a main bus bar portion and a separate bus bar tab extension connected to the main bus bar portion;

FIG. 19B is a perspective view of the power module assembly of FIG. 19A, showing the top lid removed so that the bus bar assembly is visible, showing that the bus bar assembly includes a printed circuit board arranged on the DC+ bus bar, dies formed on the DC+ bus bar, ribbon bonds, and an extended surface including pin fins formed on the output bus bar, and showing the bus bar extensions connected to the respective DC+ and output bus bars;

FIG. 20 is an exploded view of the power module assembly of FIG. 19A, showing the bus bar assembly arranged in the main frame body, showing the openings in the main frame body through which the bus bar extensions extend through and connect to the respective bus bar, and showing the DC− bus bar arranged on opposing platforms formed on the bottom lid of the frame assembly;

FIG. 21A is a top view of the main frame body and bus bar assembly of the power module assembly of FIG. 19A, showing the output and DC+ bus bars and their respective bus bar extensions;

FIG. 21B is a bottom view of the main frame body and bus bar assembly of the power module assembly of FIG. 19A, showing the DC− bus bars and its respective bus bar extension;

FIG. 22A is a bottom perspective view of the top lid of the frame assembly of the power module assembly of FIG. 19A, showing jet orifices, a top fluid outlet, and bus bar retention tabs;

FIG. 22B is a top perspective view of the bottom lid of the frame assembly of the power module assembly of FIG. 19A, showing jet orifices, a bottom fluid outlet, and bus bar retention tabs;

FIG. 23 is a cross-section view of the power module assembly of FIG. 19A, showing the bus bar assembly arranged in the main frame body, and showing fluid paths of the coolant extending from an inlet to an outlet on top and bottom sides of the bus bar assembly; and

FIG. 24 is a graphical view comparing finite element analysis results of parasitic inductance for the bus bar assembly shown in FIGS. 9-18 and the bus bar assembly shown in FIGS. 19A-23.

### DETAILED DESCRIPTION

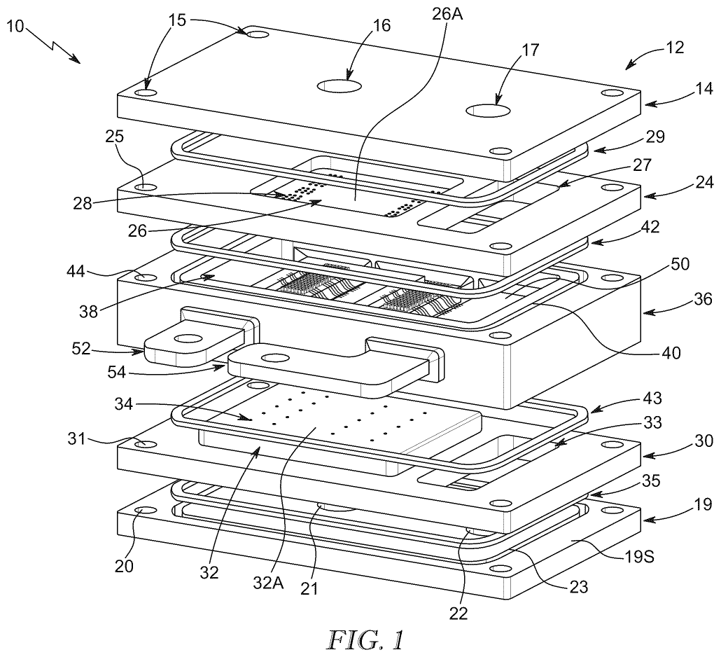

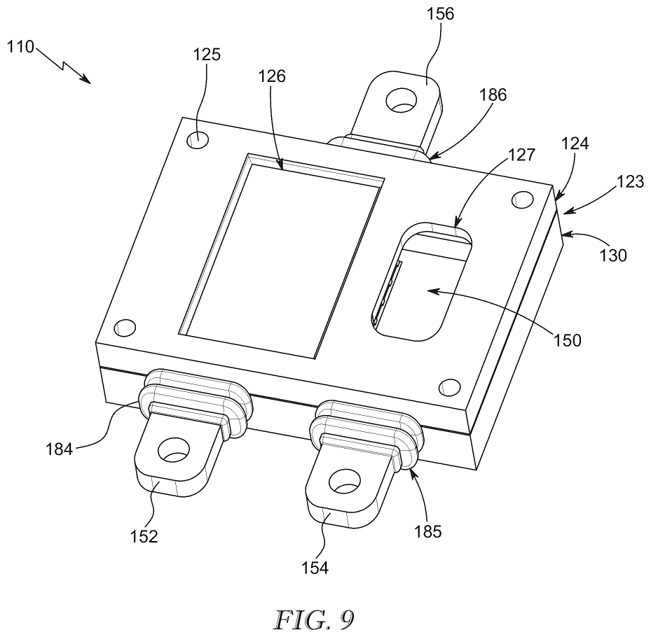

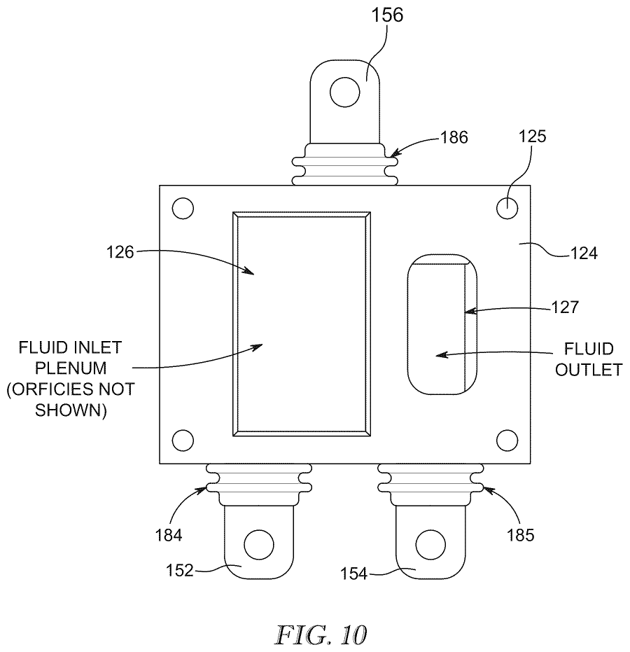

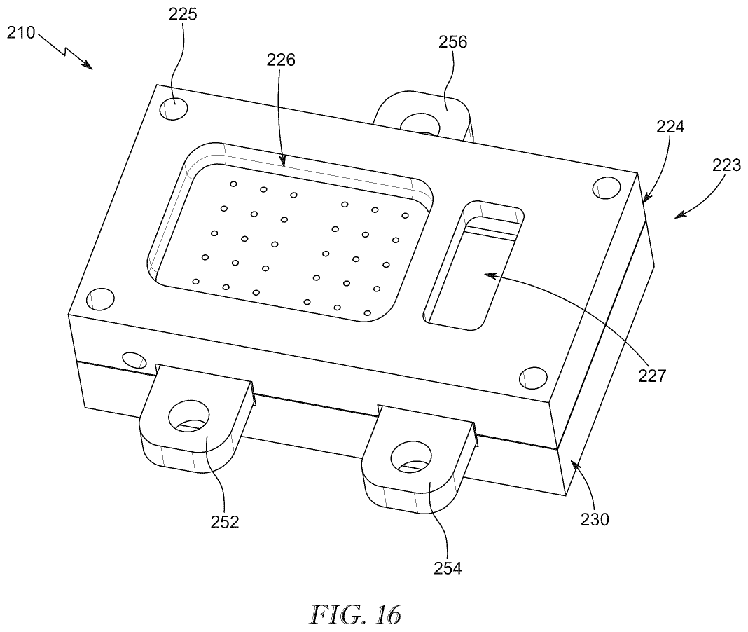

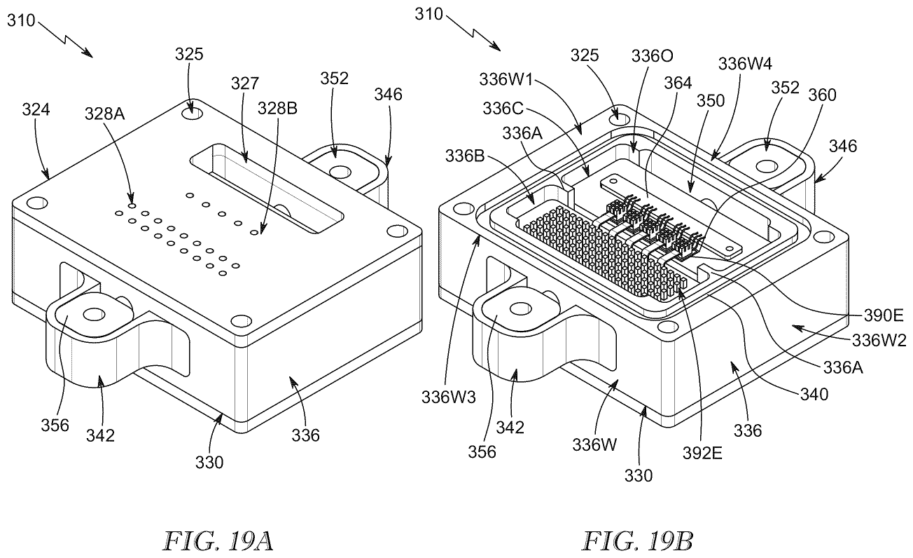

FIGS. 1-8 illustrate a power module assembly 10 according to a first aspect of the present disclosure. FIGS. 9-15B illustrate a power module assembly 110 according to a further aspect of the present disclosure. FIGS. 16-18 illustrate a power module assembly 210 according to a further aspect of the present disclosure. FIGS. 19A-23 illustrate a power module assembly 310 according to a further aspect of the present disclosure.

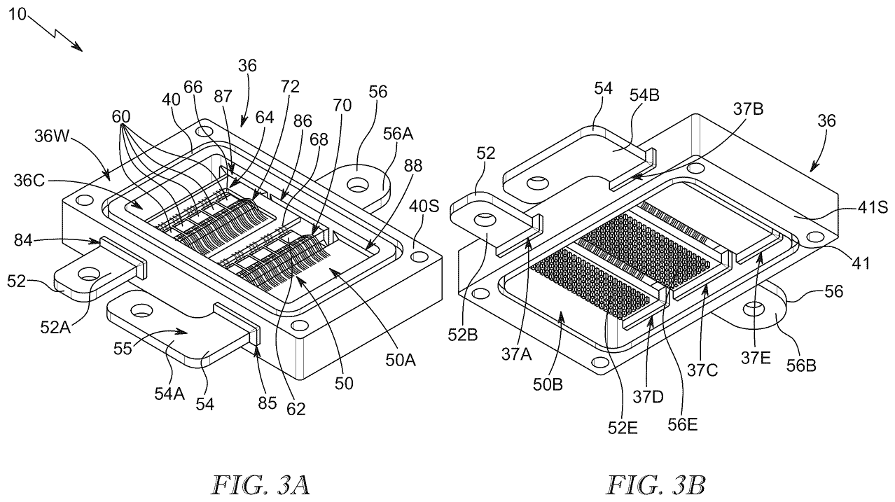

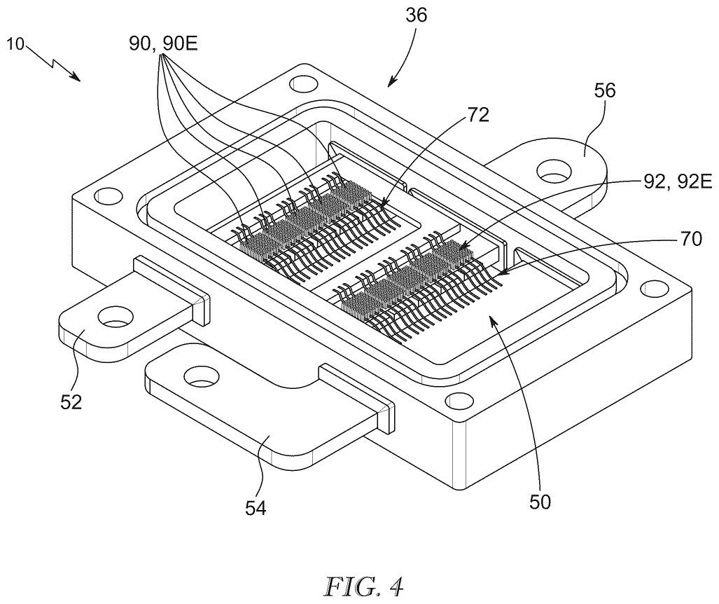

As can be seen in FIG. 1, the power module assembly 10 includes a frame assembly 12 including a top lid 14, a bottom lid 19, an upper plenum body 24, a lower plenum body 30, and a frame body 36. A bus bar assembly 50 is arranged within the frame body 36 and includes dies 60, 62 and other electrical components (see FIGS. 3B and 4, extended surfaces 90E, 92E, 52E, 56E formed as pin fins) arranged on bus bars 52, 54, 56 of the bus bar assembly 50. When assembled together such that the frame body 36 is sandwiched between the upper and lower plenum bodies 24, 30, and the upper and lower plenum bodies 24, 30 sandwiched between the top and bottom lids 14, 19, the combination of the top lid 14 and the upper plenum body 24 and the bottom lid 19 and the lower plenum body 30 each define an integrated cooling fluid manifold configured to transport coolant 98, 99 from a source (not shown) to the bus bar assembly 50, in particular the electrical components arranged on the bus bars 52, 54, 56. Specifically, the coolant 98, 99 can be discharged directly onto the electrical components of the bus bar assembly 50, thus resulting in a significant reduction of thermal impedance between the electrical components and the coolant 98, 99. It is noted that the power module assembly 10 shown in FIGS. 1-8 may be referred to as a type of “floating bus power module.”

The term “frame body” as used herein, whether in isolation or in conjunction with the terms “first,” “second,” and the like, may refer to any body that comprises a frame assembly, such as, for example, the top lid 14, the bottom lid 19, the upper plenum body 24, the lower plenum body 30, and the frame body 36 described herein. A “frame body” can also include other bodies associated with frame assemblies 123, 223, 323 described herein, such as the upper and lower frame bodies 124, 130, the top and bottom lids 324, 330, and the main frame body 336.

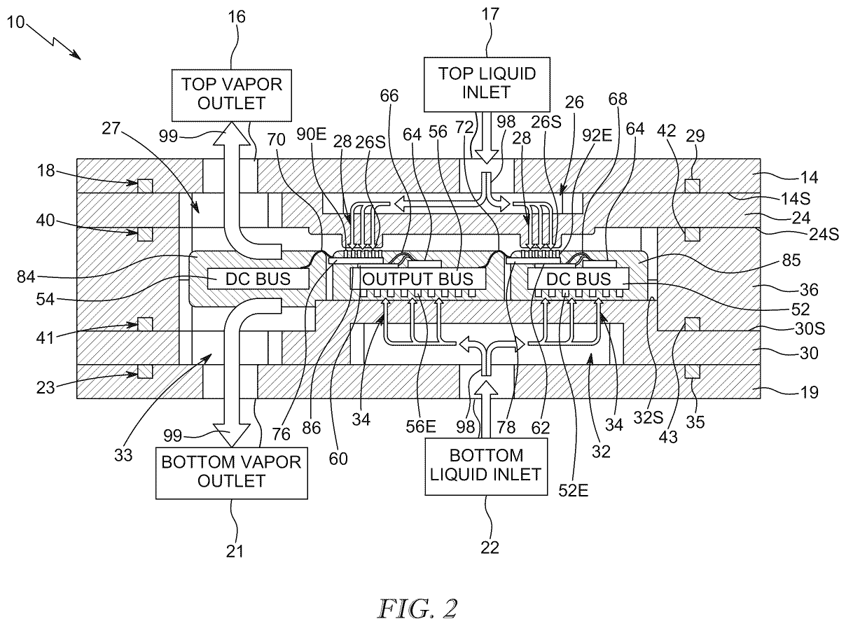

Illustratively, the top lid 14 of the power module assembly 10 is a generally planar plate, as shown in FIGS. 1 and 2. In some embodiments, the top lid 14 may be formed of metal, such as aluminum, although other suitable materials may be used. In some embodiments, the top lid 14, the bottom lid 19, the upper plenum body 24, the lower plenum body 30, and the frame body 36 being formed of metal may provide mechanical robustness and chemical compatibility in certain applications. The top lid 14, as well as the bottom lid 19, the upper plenum body 24, the lower plenum body 30, and the frame body 36, each include at least one mounting hole 15, 20, 25, 31, 44 extending through a thickness of the respective component, through which fasteners (not shown) may extend to couple the top lid 14, the bottom lid 19, the upper plenum body 24, the lower plenum body 30, and the frame body 36 to each other to form the power module assembly 10. In the illustrative embodiment, each of the top lid 14, the bottom lid 19, the upper plenum body 24, the lower plenum body 30, and the frame body 36 includes four mounting holes 15, 20, 25, 31, 44.

Similar to the top lid 14, the bottom lid 19 of the power module assembly 10 is a generally planar plate, as shown in FIGS. 1 and 2. In some embodiments, the bottom lid 19 may be formed of metal, such as aluminum, although other suitable materials may be used.

The top lid 14 further includes an inlet 16 and an outlet 17 each formed as an opening extending through a thickness of the top lid 14, as shown in FIGS. 1 and 2. The inlet 16 is spaced apart from the outlet 17 in the longitudinal direction of the top lid 14. The inlet 16 is aligned with a jet orifice recess 26 formed in the upper plenum body 24 and the outlet 17 is aligned with a vapor outlet 27 formed in the upper plenum body 24. Similarly, the bottom lid 19 further includes an inlet 22 and an outlet 23 each formed as an opening extending through a thickness of the bottom lid 19, as shown in FIGS. 1 and 2. The inlet 22 is spaced apart from the outlet 23 in the longitudinal direction of the bottom lid 19. The inlet 22 is aligned with a jet orifice recess 32 formed in the lower plenum body 30 and the outlet 23 is aligned with a vapor outlet 33 formed in the lower plenum body 30.

Each of the top and bottom lids 14, 19 further includes a seal groove 18, 23 extending generally around a perimeter of an inwardly facing surface 14S, 19S of the top and bottom lid 14, 19, respectively, as shown in FIGS. 1 and 2. The seal groove 18, 23 receives a seal 29, 35 therein, which may be formed as an O-ring seal. The seals 29, 35 cooperate with other seals 42, 43 described herein to hermetically seal the bus bar assembly 50 from the outside environment.

Illustratively, the upper plenum body 24, also referred to as an upper frame body, is a generally planar plate, as shown in FIGS. 1 and 2. In some embodiments, the upper plenum body 24 may be formed of metal, such as aluminum, although other suitable materials may be used. In order to route coolant 98, 99 from the inlet 16 of the top lid 14 to the electrical components on an upper side 50A of the bus bar assembly 50, the upper plenum body 24 includes the first jet orifice recess 26 formed therein. Specifically, the first jet orifice recess 26 is formed to open outwardly toward the inlet 16 so as to receive inlet coolant 98 therein from the inlet 16. Although a rectangular recess 26 is shown in FIG. 1, other shapes may be used based on the cooling needs of the bus bar assembly 50. The size and shape of the first jet orifice recess 26 maybe configured to meet the size and shape of the electrical components on the bus bar assembly 50, as well as the number of jet orifices 28 included in the first jet orifice recess 26.

The first jet orifice recess 26 further includes jet orifices 28 that extend through the bottom surface 26A of the first jet orifice recess 26, as shown in FIGS. 1 and 2. The jet orifices 28 can be arranged in any arrangement on the surface 26A based on the cooling needs of the power module assembly 10, such as the shape and size of the electrical components on the upper side 50A of the bus bar assembly 50 or the location of hot spots of the components on the upper side 50A of the bus bar assembly 50. For example, the jet orifices 28 may be arranged in parallel lines, as shown in FIGS. 1 and 2, in order to direct inlet coolant 98 to locations of the dies 60, 62 arranged on the bus bar assembly 50, as shown in FIGS. 3-6. Any suitable number, arrangement, and size of jet orifices 28 may be included on the upper plenum body 24 in order to meet the cooling needs of the power module assembly 10. The number and diameter of jet orifices 28 can be balanced to provide adequate flow to the top and bottom sides of the module 10 in parallel.

In some embodiments, as can be seen in FIG. 2, the inner surface 26S of the first jet orifice recess 26 that faces the bus bar assembly 50 may be raised away from a main surface 24S of the upper plenum body 24. In this way, the jet orifices 28 can be arranged directly adjacent to the electrical components that need cooling, which can be, for example, the extended surfaces 90E, 92E, as shown in FIG. 2.

The upper plenum body 24 further includes the first vapor outlet 27 spaced apart from the first jet orifice recess 26, as shown in FIGS. 1 and 2. The first vapor outlet 27 is formed as a large hole through the body 24, and is sized and shaped to receive spent coolant 99 that has passed over and cooled the electrical components on the upper side 50A of the bus bar assembly 50. The spent coolant 99 is routed from the first vapor outlet 27 and to the outlet 17 formed in the top lid 14.

Similar to the upper plenum body 24, the lower plenum body 30, also referred to as a lower frame body, is a generally planar plate, as shown in FIGS. 1 and 2. In some embodiments, the lower plenum body 30 may be formed of metal, such as aluminum, although other suitable materials may be used. In order to route coolant 98, 99 from the inlet 21 of the bottom lid 19 to the electrical components on the bottom side 50B of the bus bar assembly 50, the lower plenum body 30 includes a second jet orifice recess 32 formed therein. Specifically, the second jet orifice recess 32 is formed to open outwardly toward the inlet 21 so as to receive inlet coolant 98 therein from the inlet 21. Although a rectangular recess 32 is shown in FIG. 1, other shapes may be used based on the cooling needs of the bus bar assembly 50.

The size and shape of the second jet orifice recess 32 can be configured to meet the size and shape of the electrical components on the bus bar assembly 50, as well as the number of jet orifices 34 included in the recess 32. Illustratively, the second jet orifice recess 32 can be formed to be larger than the first jet orifice recess 26 (i.e. includes a longer longitudinal extent than the first jet orifice recess 26, as shown in FIGS. 1 and 2) so as to cool a larger area than the first jet orifice recess 26. For example, FIG. 2 illustrates first extended surfaces 90E, 92E arranged above and second extended surfaces 52E, 56E arranged below the DC+ bus bar 52 and the output bus bar 56 of the bus bar assembly 50, respectively. Because the second extended surfaces 52E, 56E occupy a greater amount of space than first extended surfaces 90E, 92E, the second jet orifice recess 32 is longer and larger than the first jet orifice recess 26 in order to effectively cool the second extended surfaces 52E, 56E.

The second jet orifice recess 32 further includes jet orifices 34 that extend through the bottom surface 32A of the recess 32, as shown in FIGS. 1 and 2. The jet orifices 34 can be arranged in any arrangement on the surface 32A based on the cooling needs of the power module assembly 10, such as the shape and size of the electrical components on the bottom side 50B of the bus bar assembly 50 or the location of hot spots of components on the bottom side 50B of the bus bar assembly 50. For example, the jet orifices 34 may be arranged in parallel lines, as shown in FIGS. 1 and 2, in order to direct inlet coolant 98 to locations of the extended surfaces 52E, 56E arranged on the bus bar assembly 50, as shown in FIGS. 3-6. Any suitable number, arrangement, and size of jet orifices 34 may be included on the lower plenum body 30 in order to meet the cooling needs of the power module assembly 10. As a non-limiting example, the jet orifices 34 of the second jet orifice recess 32 may be more spaced apart in the longitudinal direction than the jet orifices 28 of the first jet orifice recess 26 so as to effectively cool the second extended surfaces 52E, 56E.

In some embodiments, as can be seen in FIG. 2, the inner surface 32S of the second jet orifice recess 32 that faces the bus bar assembly 50 may be raised away from a main surface 30S of the lower plenum body 30. In this way, the jet orifices 34 can be arranged directly adjacent to the electrical components that need cooling, which can be, for example, the extended surfaces 52E, 56E, as shown in FIG. 2.

The lower plenum body 30 further includes the second vapor outlet 33 spaced apart from the second jet orifice recess 32, as shown in FIGS. 1 and 2. The second vapor outlet 33 is formed as a large hole through the body 30, and is sized and shaped to receive spent coolant 99 that has passed over and cooled the electrical components on the bottom side 50B of the bus bar assembly 50. The spent coolant 99 is routed from the second vapor outlet 33 and to the outlet 22 formed in the bottom lid 19.

As shown in FIGS. 1 and 2, and in greater detail in FIGS. 3A-6, the frame body 36 is a generally planar plate and is formed to provide a rigid housing to hold the bus bar assembly 50 in a fixed position. In some embodiments, the frame body 36 may be formed of metal, such as aluminum, although other suitable materials may be used. The frame body 36 may be formed to be thicker than the top lid 14, the bottom lid 19, the upper plenum body 24, and the lower plenum body 30 in order to effectively house all components of the bus bar assembly 50. Illustratively, the top lid 14, the bottom lid 19, the upper plenum body 24, the lower plenum body 30, and the frame body 36 are formed with identical lengths and widths so as to align with each other when assembled into the power module assembly 10, as shown in FIG. 2. The top lid 14, the bottom lid 19, the upper plenum body 24, the lower plenum body 30, and the frame body 36 need not be formed identically in all embodiments in order for the power module assembly 10 to operate effectively.

Similar to the top and bottom lids 14, 19, the frame body 36 further includes seal grooves 40, 41 on upper and bottom surfaces 40S, 41S of the frame body 36, as shown in FIGS. 3A and 3B. The seal grooves 40, 41 extend generally around a perimeter of the frame body 36. The seal grooves 40, 41 each receive a seal 42, 43 therein, which may be formed as an O-ring seal. The seals 42, 43 cooperate with other seals 29, 35 described herein to hermetically seal the bus bar assembly 50 from the outside environment.

As will be described in greater detail below, for external electrical connections, a DC+ bus bar 52, a DC− bus bar 54, and an output bus bar 56 are passed through respective walls 36W of the frame body 36 and are sealed by polymer flanges 84, 85, 86 arranged on the bus bars 52, 54, 56. Illustratively, the walls 36W of the frame body 36 define a large central opening 36C within which the components of the bus bar assembly 50 are housed. The upper and lower plenum bodies 24, 30 enclose the central opening 36C, which may also be referred to as a chamber 36C when enclosed by the upper and lower plenum bodies 24, 30.

As shown in FIGS. 3A and 3B, the bus bar assembly 50 includes a DC+ bus bar 52, a DC− bus bar 54, and an output bus bar 56. In some embodiments, the bus bars 52, 54, 56 may be arranged parallel to each other, and in some embodiments, the DC+ bus bar 52 and the DC− bus bar 54 may extend out of the frame body 36 on one side of the body 36 and the output bus bar 56 may extend out of the frame body 36 on an opposing side of the body 36. In some embodiments, the DC− bus bar 54 may include a bend 55 external to the frame body 36. In some embodiments, the bus bars 52, 54, 56 may be formed of copper or another suitable material.

Illustratively, the bus bar assembly 50 includes a first plurality of dies 60 arranged on an upper surface 52A of the DC+ bus bar 52 within the opening 36C of the frame body 36, as shown in FIG. 3A. The bus bar assembly 50 further includes a second plurality of dies 62 arranged on an upper surface 56A of the output bus bar 56 within the opening 36C of the frame body 36. A printed circuit board (PCB) 64 is arranged on the DC+ bus bar 52 and the output bus bar 56 and extends between and interconnects the DC+ bus bar 52 and the output bus bar 56. The PCB is illustrated to represent connections to a gate and kelvin pads on the dies, which may be included in some embodiments.

Wires 66, 68 can be included to electrically connect the PCB 64 to the dies 60, 62. Wire bonds 70, 72 can also be included to electrically connect the dies 60, 62 to the adjacent bus bars 54, 56, specifically first wire bonds 70 that connect the dies 62 to the DC− bus bar 54 on an upper surface 54A thereof, and second wire bonds 72 that connect the dies 60 to the output bus bar 56 on the upper surface 56A. The wire bonds 70, 72 provide flexibility to prevent mechanical failure due to thermal expansion and varying coefficients of thermal expansion (CTE). Copper ribbon bonds, which are used in other embodiments described herein, or any other electrical connector suitable for this purpose could be used as an alternative to wire bonds.

In the illustrative embodiment, the first plurality of dies 60 and the second plurality of dies 62 each include five dies 60, 62. This embodiment is merely exemplary, and other combinations of electrical components may be arranged on the bus bars 52, 54, 56, including the first and second pluralities of dies 60, 62 having the same or different numbers of dies, as used by the particular applications of the power module assembly 10. FIG. 3A also shows that the dies 60, 62 may be formed as bare dies that are directly exposed to the coolant 98, 99 with no extended surfaces (i.e. the extended surfaces 52E, 56E formed as pin fins shown in FIG. 3B) attached to the top of the dies 60, 62. As will be described in detail below, the dies 60, 62 may be covered in other configurations of the bus bar assembly 50.

As shown in FIG. 3B, some bus bars 52, 54, 56 may include extended surfaces that extend away from the bus bar and receive coolant 98, 99 to cool the bus bars 52, 54, 56. Illustratively, the DC+ bus bar 52 may include a plurality of extended surfaces 52E that extend away from a bottom surface 52B of the DC+ bus bar 52. Similarly, the output bus bar 56 may include a plurality of extended surfaces 56E that extend away from a bottom surface 56B of the output bus bar 56. The ends of the extended surfaces 52E, 56E can be directly exposed to the impinging jets of coolant 98 received from the jet orifices 34 of the lower plenum body 30. Any suitable arrangement and/or number of extended surfaces 52E, 56E may be arranged on the bus bars 52, 56 depending on the cooling needs of the bus bar assembly 50, including arranging additional extended surfaces on the DC− bus bar 54. In some embodiments, the extended surfaces 52E, 56E may be formed as pin fins machined into the bus bars 52, 56 in order to provide extended heat transfer surfaces. Other suitable enhanced heat transfer surfaces which increase heat transfer efficiency, also referred to herein as surface enhancements, could be fabricated on the bus bars 52, 54, 56 and copper blocks 90, 92 on top of the dies 60, 62 depending on the cooling needs and design specifications of the power module assembly 10, such as, for example, parallel walls of a heat sink forming channels, honeycomb pins, porous coatings, increased surface roughness, and the like.

Illustratively, the bus bar assembly 50 further includes insulating flanges 84, 85, 86 that are arranged in respective openings 37A, 37B, 37C formed in the walls 36W of the frame body 34 and surround the portions of the respective bus bars 52, 54, 56 that pass through the openings 37A, 37B, 37C, as shown in FIGS. 3A and 3B. In some embodiments, the insulating flanges 84, 85, 86 are formed of a non-conductive material, such as a polymer, so as to insulate the bus bars 52, 54, 56 from the frame body 36. Moreover, the ends of the DC+ and DC− bus bars 52, 54 that do not extend through the frame body 36 may rest within recesses 37D, 37E that do not extend fully through the frame body 36. Further insulating flanges 87, 88 may be arranged within these recesses 37D, 37E in order to insulate the ends of the DC+ and DC− bus bars 52, 54. A similar recess and flange may be provided for the opposing end of the output bus bar 56 (not shown). In some embodiments, the insulating flanges 84, 85, 86, 87, 88 may be formed by permanently bonding the polymer material to the bus bars 52, 54, 56 using an overmolding process where a plastic is injection molded directly onto a substrate.

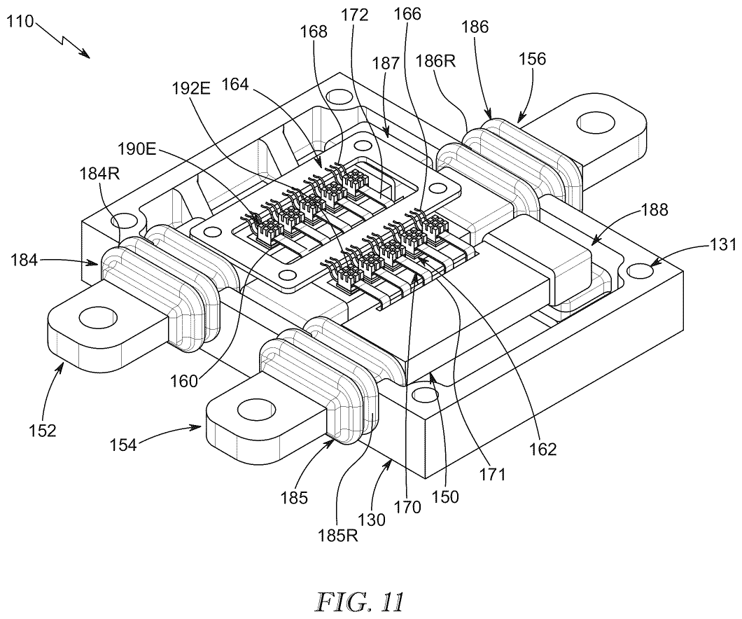

In some embodiments, as shown in FIG. 4, the bus bar assembly 50 can include separate copper blocks 90, 92 arranged on a top side of the bare dies 60, 62. The copper blocks 90, 92 may be formed as individual flat blocks of copper that substantially cover the dies 60, 62. The copper blocks 90, 92 may be thermally conductive. In some embodiments, extended surfaces 90E, 92E can extend away from the flat blocks of copper 90, 92, in particular extended surfaces 90E, 92E formed as machined pin fins for increased heat transfer area. The ends of the extended surfaces 90E, 92E can be directly exposed to the impinging jets of coolant 98 received from the jet orifices 28 of the upper plenum body 24. It is noted that FIG. 11 shows a more detailed view of a possible structure and arrangement of the flat blocks of copper 90, 92 and the extended surfaces 90E, 92E of FIG. 4, although it is also noted that the arrangement in FIG. 11 slightly differs from that shown in FIG. 4 in that the blocks 90, 92 have a smaller footprint and are attached to opposing bus bars using ribbon bonds instead of wire bods. In some embodiments, the individual flat blocks of copper 90, 92 can be soldered onto the source pads of each individual die 60, 62 (this can be seen more clearly in FIG. 2, which shows the source pads of the dies 60, 62 underneath the blocks 90, 92).

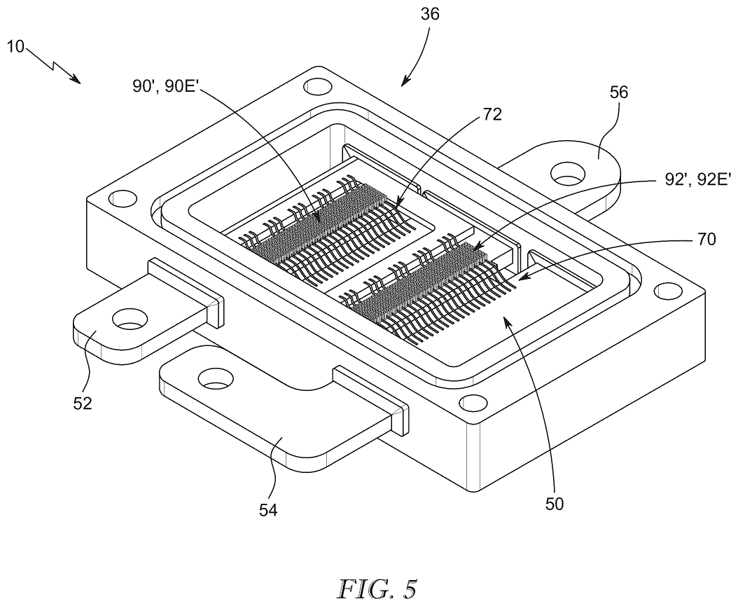

Instead of separate copper blocks 90, 92 or in place of one of the sets of copper blocks 90, 92, the bus bar assembly 50 can include an elongated copper block 90′, 92′ arranged on and extending over all of respective bare dies 60, 62 of the bus bar assembly 50, as shown in FIG. 5. Similar to the separate copper blocks 90, 92, the elongated copper blocks 90′, 92′ can include extended surfaces 90E′, 92E′ formed as machined pin fins for increased heat transfer area. This configuration may provide increased heat spreading and thermal coupling between dies 60, 62.

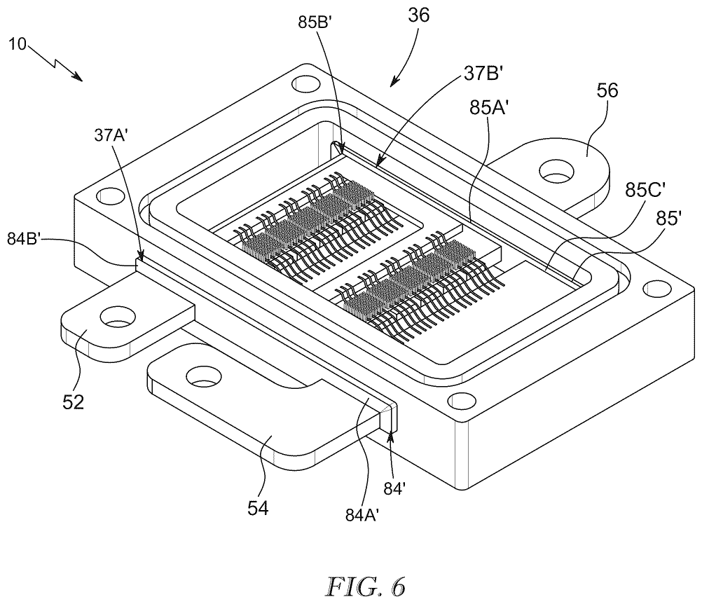

In some embodiments, instead of including multiple insulating flanges on each side of the frame body 36 as shown in FIGS. 3A and 3B, the bus bar assembly 50 can include only a single insulating flange 84′, 85′ on each side of the frame body 36, as shown in FIG. 6. Instead of multiple openings, each side of the frame body 36 only includes a single opening 37A′, 37B′. Accordingly, a first insulating flange 84′ is formed to include two openings 84A′, 84B′ that each surround a portion of a respective bus bar 52, 54 that passes through the opening 37A′. A second insulating flange 85′ is formed to include a single full opening 85A′ that surrounds a portion of the output bus bar 56 that passes through the opening 37B′. Moreover, the ends of the DC+ and DC− bus bars 52, 54 that do not extend through the frame body 36 may rest within recesses 85B′, 85C′ that do not extend fully through the second insulating flange 85′. This configuration may mitigate electrical losses due to the presence of conductive material inside the loop formed by the DC+ and DC− bus bars 52, 54.

Referring again to FIG. 2, in operation, liquid inlet coolant 98 enters through the input 16 (also referred to as a “top liquid inlet”) of the top lid 14 and into the first jet orifice recess 26 of the upper plenum body 24. The coolant 98 is directed through the jet orifices 28 and onto the electrical components of the bus bar assembly 50. Similarly, liquid inlet coolant 98 enters through the input 21 (also referred to as a “bottom liquid inlet”) of the bottom lid 19 and into the second jet orifice recess 32 of the lower plenum body 30. The coolant 98 is directed through the jet orifices 34 and onto the electrical components of the bus bar assembly 50 to cool the components, or in other words, reduce an operating temperature of the bus bar assembly 50 and its components. Specifically, the coolant 98 will boil as it absorbs heat from the dies 60, 62, extended surfaces 90E, 92E, 52E, 56E, and bus bars 52, 54, 56. The spent coolant 99, which is a two-phase mixture after having boiled, is routed through the two outlets 17, 22 (also referred to as a “top vapor outlet” and a “bottom vapor outlet”) located on the top and bottom lids 14, 19 after passing over the DC− bus bar 54 (shown on the left in FIG. 2) and through the vapor outlets 27, 33 of the plenum bodies 24, 30.

In one example, the cooling fluid may be a dielectric coolant. The cooling fluid may be deionized water, Ethylene Glycol Water (EGW), or any other suitable fluid may be used. One potential concern is that the cooling fluid may ionize quickly due to number of dissimilar metals. In another example, the cooling fluid may be a dielectric fluid such as tetrafluoroethane, also referred to as R134a, available from Linde Inc. Another example of a dielectric fluid is Honeywell Solstice® zd refrigerant, also referred to as R1233zd, available from Honeywell Belgium N.V.

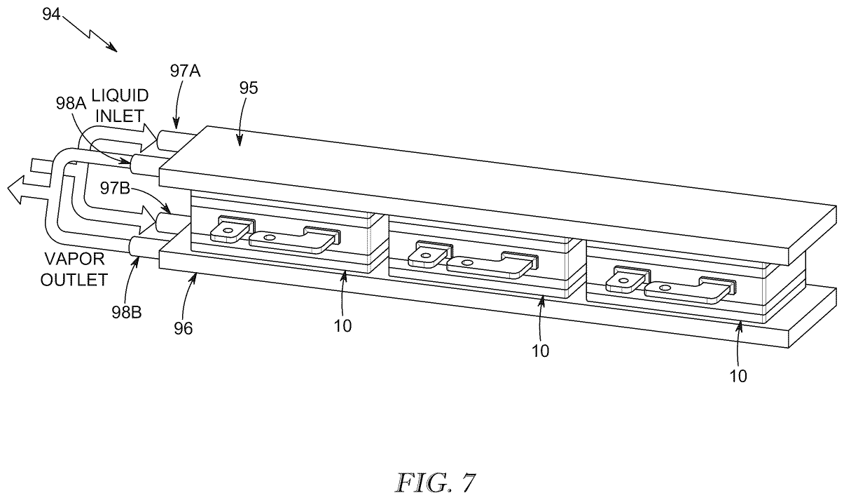

FIG. 7 shows a first configuration 94 of arranging multiple power module assemblies 10 to operate in parallel. As shown in FIG. 7, three module assemblies 10 are mounted between two manifolding plates 95, 96 which include fluid passages (not shown) therein so as to provide inlet coolant 98 routing to the top and bottom sides of each module assembly 10 in a planar, horizontal configuration. Specifically, a liquid inlet 97A, 97B is fluidically connected to each manifolding plate 95, 96 and provides the coolant 98, 99 to the fluid passages and subsequently to the inlets 16, 21 of the top and bottom lids 14, 19 of each power module assembly 10. The module assemblies 10 are hydrodynamically connected in parallel, reducing overall pressure drop. The spent coolant 99 is routed out of the configuration 94 via the vapor outlets 98A, 98B.

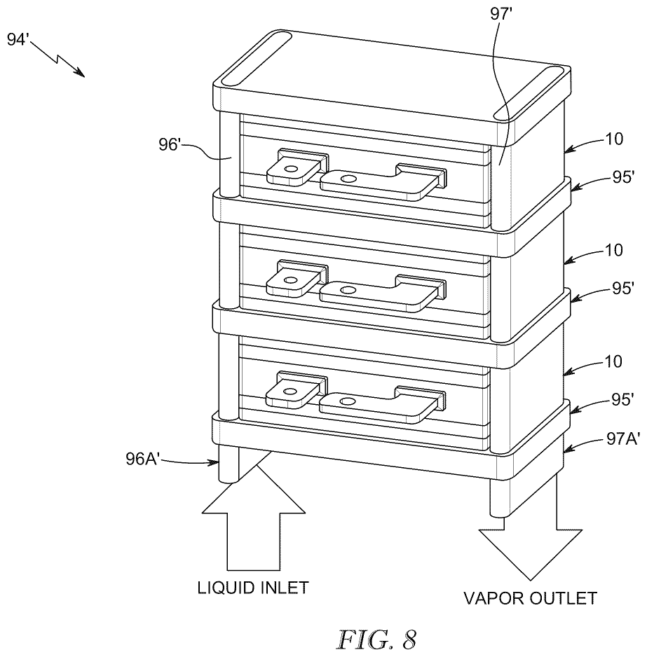

FIG. 8 shows a second configuration 94′ of arranging multiple power module assemblies 10 to operate in parallel. As shown in FIG. 8, three module assemblies 10 are mounted vertically relative to each other with separation plates 95′ arranged between each module assembly 10 and below the lowermost module assembly 10. A first vertical manifolding plate 96′ can be arranged on one side of the configuration 94′, and a second vertical manifolding plate 97′ can be arranged on an opposing side of the configuration 94′. Each manifolding plate 96′, 97′ can include fluid passages (not shown) therein so as to provide inlet coolant 98 to the module assemblies 10 from a liquid inlet 96A′ of the first manifolding plate 96′ and transport spent coolant 99 away from the module assemblies 10 and to a vapor outlet 97A′ of the second manifolding plate 97′.

Another embodiment of a power module assembly 110 is shown in FIGS. 9-15B. The power module assembly 110 is similar to the power module assembly 10 shown in FIGS. 1-8 and described herein. Accordingly, similar reference numbers in the 100 series indicate features that are common between the power module assembly 110 and the power module assembly 10. The description of the power module assembly 10 is incorporated by reference to apply to the power module assembly 110, except in instances when it conflicts with the specific description and the drawings of the power module assembly 110.

Similar to the power module assembly 10, the power module assembly 110 includes a bus bar assembly 150 including two DC bus bars 152, 154 and an output bus bar 156 arranged within a frame. Unlike the power module assembly 10, the power module assembly 110 does not include top and bottom lids nor separate plenum bodies, but instead includes two frame bodies 124, 130 that couple to each other and enclose the bus bar assembly 150, as shown in FIG. 9. It is noted that the power module assembly 110 shown in FIGS. 9-15B may be referred to as another type of “floating bus power module” similar to the floating bus power module shown in FIGS. 1-8.

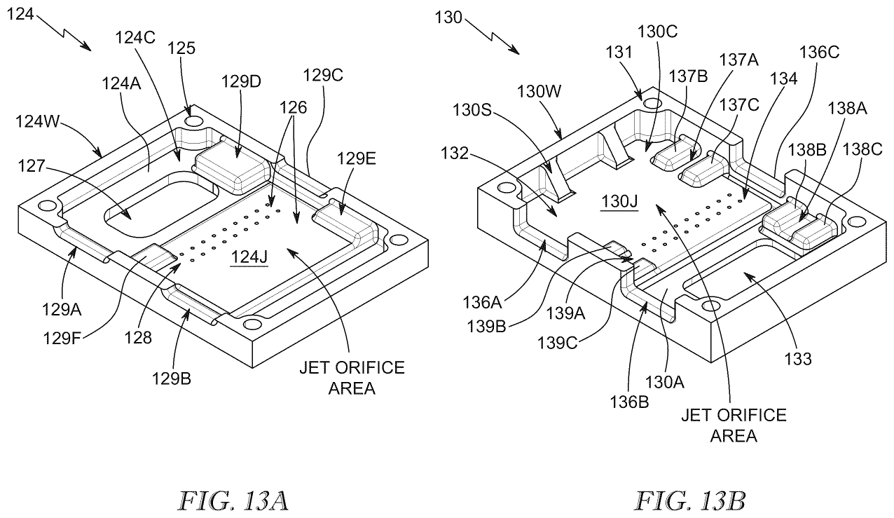

As can be seen in FIGS. 9-14, the power module assembly 110 includes a frame assembly 123 which includes a top frame body 124 and a bottom frame body 130 coupled to the top frame body 124 via fasteners (not shown) extending through mounting holes 125, 131. As shown in FIG. 9 and in more detail in FIG. 13A, the top frame body 124, also referred to as an upper frame body and similar to the upper plenum body 24, includes a first jet orifice recess 126 and a first vapor outlet 127 formed adjacent to the first jet orifice recess 126. The first jet orifice recess 126 is formed similarly to the first jet orifice recess 26 to include jet orifices 128 in a jet orifice area 124J arranged to discharge coolant 198, 199 directly onto the electrical components of the bus bar assembly 150. As shown in FIG. 9 and in more detail in FIG. 13B, the bottom frame body 130, similar to the bottom plenum body 30, includes a second jet orifice recess 132 and a second vapor outlet 133 formed adjacent to the second jet orifice recess 132. The second jet orifice recess 132 is formed similarly to the second jet orifice recess 32 to include jet orifices 134 in a jet orifice area 130J arranged to discharge coolant 198, 199 directly onto the electrical components of the bus bar assembly 150.

FIG. 11 shows a view of the bottom frame body 130 and the bus bar assembly 150 without the top frame body 124. The bus bar assembly 150 is formed similarly to the bus bar assembly 50 described herein, in particular to include the DC+ and DC− bus bars 152, 154 and an output bus bar 156 arranged parallel and adjacent to each other. The bus bar assembly 150 further includes a PCB 164 similar to the PCB 64 to facilitate gate connections, and dies 160, 162, similar to the dies 60, 62, arranged on the DC+ bus bar 152 and the output bus bar 156. The bus bar assembly 150 further includes extended surfaces 190E, 192E extending away from the dies 160, 162 and ribbon bonds 170, 172 used instead of the wire bonds described herein.

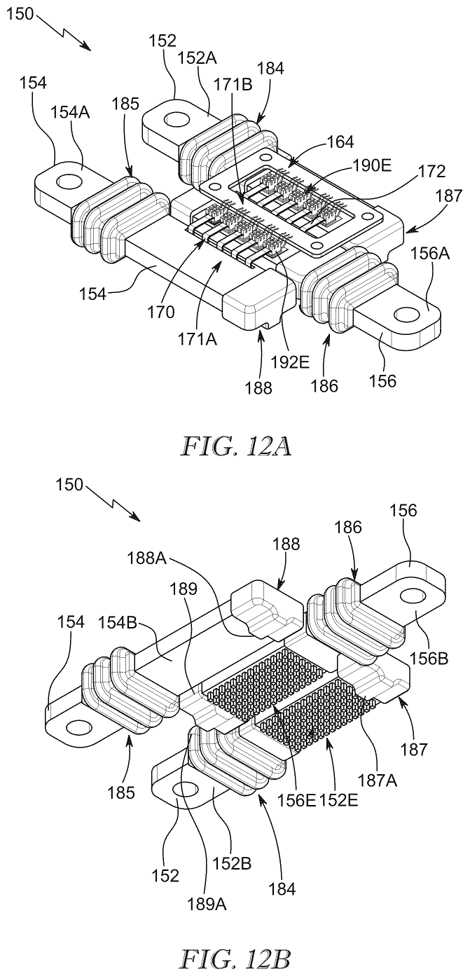

In some embodiments, as shown in detail in FIG. 12A, the bus bar assembly 150 can include MOSFET dies 162 arranged only on the output bus bar 156 or MOSFET dies 160, 162 arranged on both of the DC+ bus bar 152 and the output bus bar 156. Drains of the MOSFET dies 160, 162 are bonded onto the top surfaces 152A, 156A of the DC+ and output bus bars 152, 156. In some embodiments, the ribbon bonds 170, 172 extending from each of the MOSFET dies 160, 162 extend into slots 171A, 171B formed in respective DC+ and output bus bars 152, 156, as shown in FIG. 12A. Arranging the bonds 170, 172 within the slots 171A, 171B may increase mechanical strength and lower electrical resistance as compared to other components such as wire bonds.

Illustratively, as shown in FIG. 12B, the DC+ bus bar 152 may include a plurality of extended surfaces 152E that extend away from a bottom surface 152B of the DC+ bus bar 152. Similarly, the output bus bar 156 may include a plurality of extended surfaces 156E that extend away from a bottom surface 156B of the output bus bar 156. The ends of the extended surfaces 152E, 156E can be directly exposed to the impinging jets of coolant 198 received from the jet orifices 134.

Similar to the bus bar assembly 50, the bus bar assembly 150 further includes insulating flanges 184, 185, 186 that surround the portions of the respective bus bars 152, 154, 156 that extend out of the frame assembly 123, as shown in FIGS. 11-12B. The insulating flanges 84, 85, 86 are formed of a non-conductive material, such as a polymer, so as to insulate the bus bars 152, 154, 156 from the frame bodies 124, 130. The ends of the DC+ and DC− bus bars 152, 154 and the output bus bar 156 that do not extend out of the frame assembly 123 may include non-conductive end caps 187, 188, 189 formed of a non-conductive material such as a polymer. The end caps 187, 188, 189 insulate the ends of the bus bars 152, 154, 156 from the frame bodies 124, 130. In some embodiments, ridges 184R, 185R, 186R can be included in the flanges 184, 185, 186 (and in the end caps 187, 188, 189 in some embodiments) to provide surface creepage resistance and pins molded into the flanges 184, 185, 186, as shown in FIGS. 11-12B.

As can be seen in FIGS. 11-13B, the bus bar assembly 150 rests on portions of the bottom frame body 130 so as to secure the assembly 150 between the top and bottom frame bodies 124, 130. Specifically, the bottom frame body 130, also referred to herein as a lower frame body, includes walls 130W that extend around a perimeter of the body 130 and define a shallow cavity 130C therebetween. In some embodiments, the walls 130W may be supported by frame support gussets 130S staggered around the extent of the walls 130W. A first wall 130W on a first side of the bottom frame body 130 includes two notches 136A, 136B formed therein. The notches 136A, 136B provide a surface within which the DC+ and DC− bus bars 152, 154 can be arranged and, in some embodiments, bonded to the bottom frame body 130 via permanent epoxy or similar means. An opposing wall 130W on a second opposing side of the bottom frame body 130 includes a single notch 136C formed therein. The notch 136C provides a surface within which the output bus bar 156 can be arranged and, in some embodiments, bonded to the bottom frame body 130 via permanent epoxy or similar means.

Key slots 137A, 138A, 139A can be formed opposite each notch 136A, 136B, 136C, as shown in FIG. 13B. The key slots 137A, 138A, 139A can each be formed by two opposing ridges 137B, 137C, 138B, 138C, 139B, 139C that protrude away from the bottom surface 130A of the body 130 and contact the adjacent wall 130W. A corresponding key 187A, 188A, 189A, as shown in FIG. 12B, can be formed in each respective end cap 187, 188, 189, the key 187A, 188A, 189A being formed to fit securely within the respective key slot 137A, 138A, 139A. This arrangement provides additional mechanical rigidity to the bus bars 152, 154, 156 to prevent damage during attachment of electrical connections to the external ends of the bus bars 152, 154, 156.

As shown in FIG. 13A, the top frame body 124 is formed similarly to the upper plenum body 24, but instead is formed to include perimeter walls 124W extending away from an upper surface 124A of the body 124 and defining a shallow cavity 124C into which the first jet orifice recess 126 protrudes (as this “recess” is recessed from the opposing surface of the body 124, i.e. the bottom of the body 124 as viewed in FIG. 13A). The jet orifices 128 are arranged on the first jet orifice recess 126 in the jet orifice area 124J. The top frame body 124 includes notches 129A, 129B, 129C that correspond to the notches 136A, 136B, 136C of the bottom frame body 130, and further includes end supports 129D, 129E, 129F that are aligned with the ridges 137B, 137C, 138B, 138C, 139B, 139C and support the side of the respective end cap 187, 188, 189 opposite the side supported by the ridges 137B, 137C, 138B, 138C, 139B, 139C.

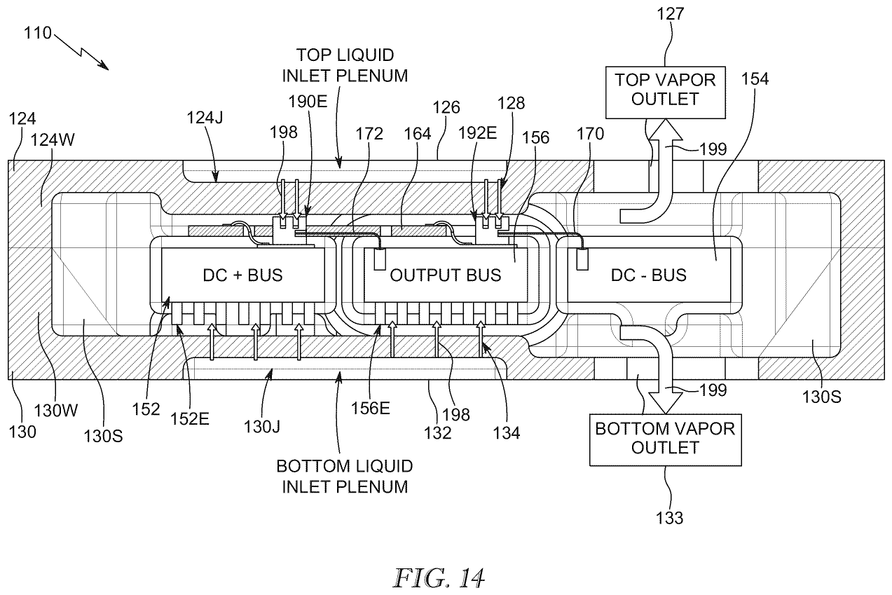

Illustratively, the power module assembly 110 can be assembled by first arranging the bus bar assembly 150 on the bottom frame body 130 such that the insulating flanges 184, 185, 186 of the bus bars 152, 154, 156 rest in the notches 136A, 136B, 136C. The flanges 184, 185, 186 can then be epoxied to the surfaces of the notches 136A, 136B, 136C. The top frame body 124 can then placed on top of the bottom frame body 130, and fasteners (not shown) can be inserted through the mounting holes 125, 131. Epoxy can also be used between the surfaces of the notches 129A, 129B, 129C of the top frame body 124 and the tops of the flanges 184, 185, 186, and then the fasteners can be tightened so as to secure the components together, resulting in an assembled power module assembly 110. As can be seen in FIG. 14, the power module assembly 110 operates similar to the power module assembly 10, with inlet coolant 198 flowing from an external source to jet orifice recesses 126, 132, through the jet orifices 128, 134, onto a corresponding electrical component of the bus bar assembly 150, and then out of the power module assembly 110 via the vapor outlets 127, 133.

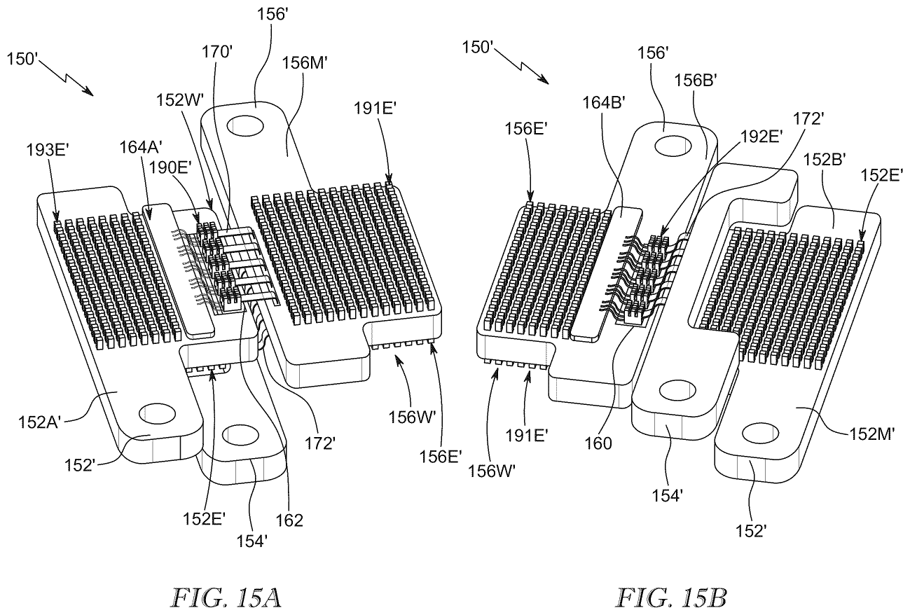

FIGS. 15A and 15B show an alternative arrangement of a bus bar assembly 150′ that may be used in the power module assembly 110. An important electrical design objective of the power module assemblies described herein is to minimize the parasitic induction in the DC current loop path. While the planar configuration of the bus bar assembly 150 shown in FIGS. 9-12B provides many advantages, that configuration may lead to DC loop induction. One example of an alternative bus bar design that may aid in reducing and/or minimizing DC loop induction is shown in FIGS. 15A and 15B.

In FIGS. 15A and 15B, the DC+ and DC− bus bars 152′, 154′ are stacked vertically. The DC+ bus bar 152′ remains in the same orientation as shown in the configuration of FIGS. 9-12B, while the output bus bar 156′ is flipped vertically, and the DC− bus bar 154′ is arranged below the DC+ bus bar 152′. In order to accommodate this arrangement, the bottom frame body 130 may include an opening similar to the openings formed in the frame body 36 below the notch 136A for the DC+ bus bar 152′, the opening being configured to receive the DC− bus bar 154′ therethrough.

A first plurality of dies 160′ is arranged on an upper surface 152A′ of the DC+ bus bar 152′, and a second plurality of dies 162′ is arranged on the bottom surface 156B′ of the output bus bar 156′. Ribbon bonds may be used to interconnect the dies 160′ to the output bus bar 156 and to interconnect the dies 162′ to the DC− bus bar 154′. Since no dies are bonded onto the DC− bus bar 154′, the cross section of the DC− bus bar 154′ only needs to be large enough to carry current and the bus bar 154′ can be shaped to maintain access for liquid jets to impinge on the DC+ bus bar 152′. The DC+ bus bar 152′ and the output bus bar 156′ shown in FIGS. 15A and 15B also have extended wings 152W′, 156W′ for additional heat spreading to reduce heat fluxes if necessary.

An extended surface 191E′ could be machined on at least a portion of the main body 156M′ of the output bus bar 156′ and extending out onto the wing 156W′. An additional extended surface 152E′ could be machined on the bottom side 152B′ of at least a portion of the main body 152M′ of the DC+ bus bar 152′ and extending out on to the wing 152W′. Smaller extended surfaces 156E′ and 193E′ could be machined on the bottom side 156B′ of the wing 156W′ and the upper surface 152A′ of the bus bar 152′. These extended surfaces 191E′, 193E′, 152E′, 156E′ further increase available surface area for cooling purposes.

Another embodiment of a power module assembly 210 is shown in FIGS. 16-18. The power module assembly 210 is similar to the power module assemblies 10, 110 shown in FIGS. 1-15B and described herein. Accordingly, similar reference numbers in the 200 series indicate features that are common between the power module assembly 210 and the power module assemblies 10, 110. The descriptions of the power module assemblies 10, 110 are incorporated by reference to apply to the power module assembly 210, except in instances when they conflict with the specific description and the drawings of the power module assembly 210.

Similar to the power module assembly 110, the power module assembly 210 includes a bus bar assembly 250 including two DC bus bars 252, 254 and an output bus bar 256 arranged within a frame assembly 223. Unlike the top and bottom frame bodies 124, 130 of the power module assembly 110, the top and bottom frame bodies 224, 230 are not made of metal, but instead are made of a non-conductive material such as a polymer, which may include, for example, Nylon or PEEK. Because the top and bottom frame bodies 224, 230 are not conductive, the bus bars 252, 254, 256 can be arranged directly in contact with the bodies 224, 230, thus eliminating the need for the insulating flanges 184, 185, 186 and end caps 187, 188 of the power module assembly 110. It is noted that the power module assembly 210 shown in FIGS. 16-18 may be referred to as another type of “floating bus power module” similar to the floating bus power modules shown in FIGS. 1-15B.

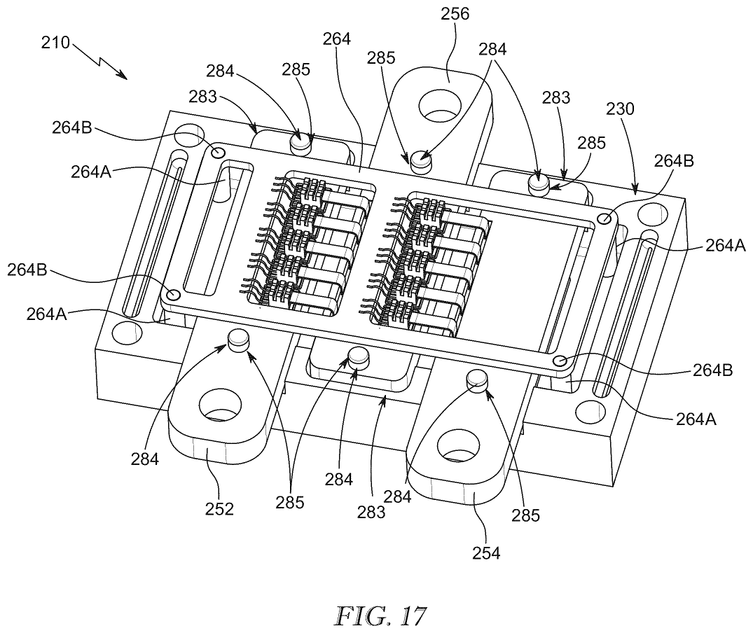

The bus bar assembly 250 is formed substantially similarly to the bus bar assembly 150, but instead does not include the insulating flanges 184, 185, 186 and end caps 187, 188, as described above. Instead, each bus bar 252, 254, 256 includes holes 284 at opposing sides of the bus bar that are formed to align with corresponding pins 285 of the bottom frame body 230 in order to secure the bus bar 252, 254, 256 in position with respect to the bottom frame body 230. As can be seen in FIG. 17, each bus bar 252, 254, 256 includes two holes 284 through which the pins 285 extend.

Another difference between the bus bar assembly 150 and the bus bar assembly 250 is that the PCB 264 is formed to extend over the DC− bus bar 254 in addition to the DC+ bus bar 252 and the output bus bar 256. The PCB 264 may also be formed to rest on and be secured to stepped pegs 264A that extend upwardly from a bottom surface 230S of the bottom frame body 230. The top ends of the pegs 264A are stepped and extend through holes 264B formed in the four corners of the PCB 264 so as to allow the PCB 264 to rest on the ledges of the stepped portions of the pegs 264A. Other suitable methods of supporting the PCB 264 are contemplated, such as supporting the PCB 264 directly on the bus bars 252, 254, 256 or via other supporting structures within the frame assembly 223.

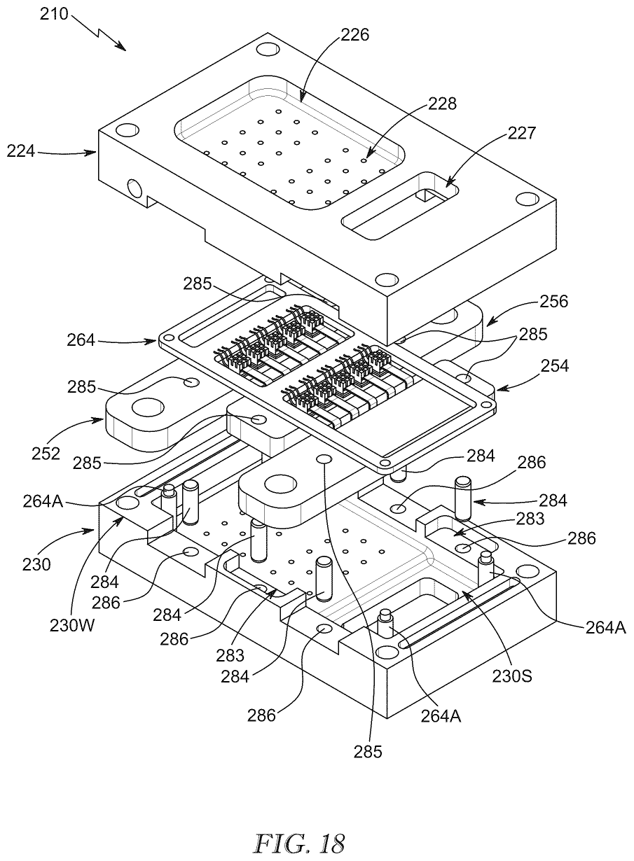

As can be seen in FIGS. 17 and 18, the top and bottom frame bodies 224, 230 may be formed substantially similarly to the top and bottom frame bodies 124, 130, for example, with regard to their shape, size, and arrangement of the orifices 228, 234 and vapor outlets 227, 233. The bottom frame body 230 differs in that the walls 230W of the body 230 include a plurality of holes 286 formed in the top surface of the wall 230W around the perimeter of the body 230. The holes 286 are configured to receive the pins 285 which extend through and secure the bus bars 252, 254, 256 to the bottom frame body 230. The walls 230W also include recesses 283 formed therein to receive free ends of the bus bars 252, 254, 256, as opposed to the insulating end caps 187, 188 described herein.

Another embodiment of a power module assembly 310 is shown in FIGS. 19A-23. The power module assembly 310 is similar to the power module assemblies 10, 110, 210 shown in FIGS. 1-18 and described herein. Accordingly, similar reference numbers in the 300 series indicate features that are common between the power module assembly 310 and the power module assemblies 10, 110, 210. The descriptions of the power module assemblies 10, 110, 210 are incorporated by reference to apply to the power module assembly 310, except in instances when they conflict with the specific description and the drawings of the power module assembly 310.

The power module assembly 310 is constructed similarly to the power module assembly 10 of FIGS. 1-8, in particular to include a central, main frame body 336 and top and bottom lids 324, 330 enclosing the main frame body 336. The top and bottom lids 324, 330 include the jet orifices 328, 334 through which coolant 398, 399 is directed to the bus bar assembly 350, as will be described in greater detail below.

The power module assembly 310 differs from the power modules 10, 110, 210 in that the module assembly 310 is a “folded bus bar configuration,” which includes the DC+ and DC− bus bars 352, 354 in an aligned, stacked arrangement on one side of the main frame body 336, and the output bus bar 356 on an opposing side of the main frame body 336, as shown in FIGS. 19A-21B. The folded bus bar configuration of the power module assembly 310 may provide certain advantages over the floating bus power module of the power module assemblies 10, 110, 210. For example, although the floating bus power module of the power module assemblies 10, 110, 210 may provide design simplicity and ease of manufacturing benefits, the folded bus bar configuration of the power module assembly 310 may reduce noise and losses due to parasitic inductance, and can reduce the size of the DC current path through the module, which would likely reduce losses that may be caused by such a large DC current path. This could also lead to increased switching performance.

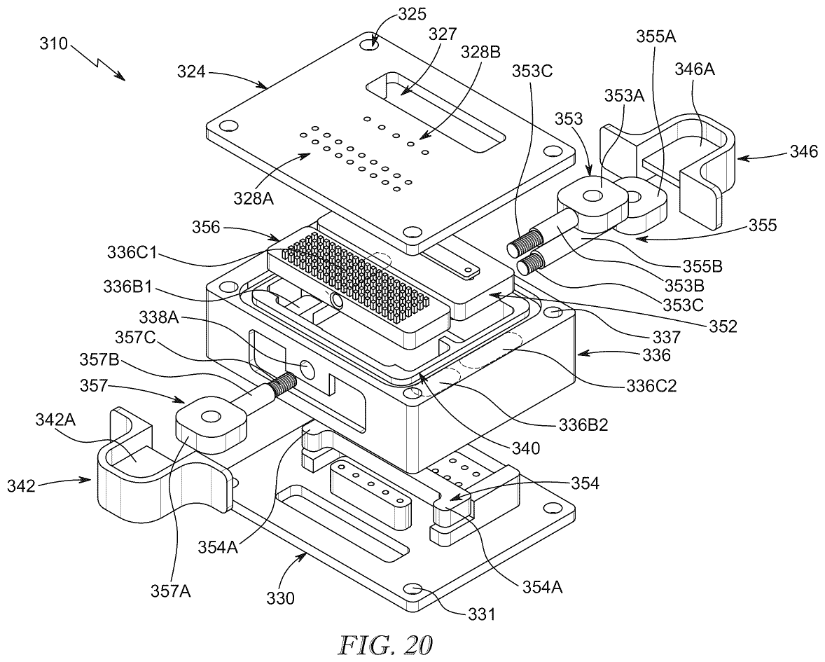

As shown in FIGS. 19A-21B, the main frame body 336 is formed similarly to the frame body 36, in particular having walls 336W that define a large central opening 3360 within which the components of the bus bar assembly 350 are housed. The main frame body 336 further includes ridges 336A that extend from opposing walls 336W1, 336W2 toward each other and into the opening 3360. The ridges 336A define an output bus bar opening 336B between the wall 336W3 and a plane extending between the ends of the ridges 336A and a DC+ bus bar opening 336C between the wall 336W4 and the plane extending between the ends of the ridges 336A. Opposing ends of the output bus bar 356 are configured to be tightly surrounded and secured within the boundaries of the output bus bar opening 336B, and opposing ends of the DC+ bus bar 352 are configured to be tightly surrounded and secured within the boundaries of the DC+ bus bar opening 336C. In some embodiments, ledges 336B1, 336C1, 336B2, 336C2 may be arranged within the ends of the output bus bar opening 336B and/or the DC+ bus bar opening 336C on which the bus bars 352, 356 rest, as shown in FIG. 20.

Unlike the top and bottom frame bodies 124, 130 of the power module assembly 110, the main frame body 336, as well as the top and bottom lids 324, 330, are not made of metal, but instead are made of a non-conductive material such as a polymer, which may include, for example, Nylon or PEEK. Because the top and bottom lids 324, 330 and the main frame body 336 are not conductive, the bus bars 352, 354, 356 can be arranged directly in contact with the lids 324, 330 and the main frame body 336, thus eliminating the need for the insulating flanges 184, 185, 186 and end caps 187, 188 of the power module assembly 110.

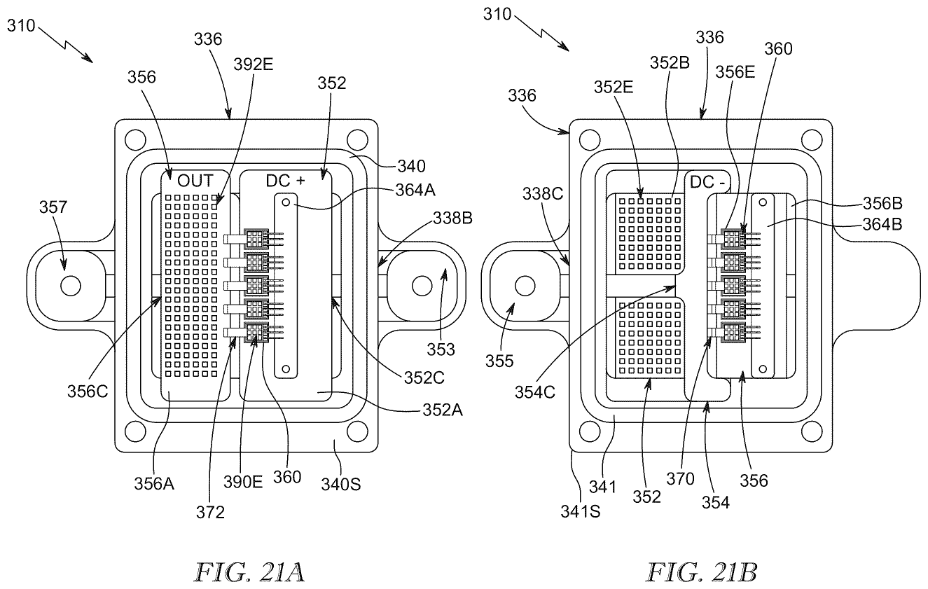

In some embodiments, similar to the frame body 36, the main frame body 336 further includes seal grooves 340, 341 extending generally around a perimeter of an outwardly facing surface 3405, 3415 of the main frame body 336, respectively, as shown in FIGS. 21A and 21B. The seal grooves 340, 341 each receive a seal therein (not shown, similar to the O-ring seals described herein). The seals hermetically seal the bus bar assembly 350 from the outside environment.

As shown in detail in 19B-21B, the bus bar assembly 350 includes two DC bus bars 352, 354 and an output bus bar 356 arranged within the main frame body 336. The bus bars 352, 354, 356 are shaped differently than the bus bars in other embodiments described herein, and are arranged differently with respect to each other as well. For example, as can be seen in FIG. 21A, the DC+ bus bar 352 is arranged in parallel with the output bus bar 356, with each extending along a longitudinal extent of the main frame body 336. In some embodiments, the DC+ bus bar 352 may be wider than the output bus bar 356.

With reference to FIG. 21A, the DC+ bus bar 352 may include a first plurality of dies 360 arranged on an upper surface 352A of the bus bar 352, and may include extended surfaces 390E formed of copper and extending from each of the dies 360. A first PCB 364A may be arranged on the upper surface 352A. The dies 360 may be interconnected with the output bus bar 356 via copper ribbon bonds 372, as shown in FIG. 21A. The output bus bar 356 may include extended surfaces 392E that extend away from the upper surface 356A of the bus bar 356.

With reference to FIG. 21B, the output bus bar 356 may include a second plurality of dies 362 arranged on a bottom surface 356B of the bus bar 356, and may include extended surfaces 356E formed of copper and extending from each of the dies 362. A second PCB 364B may be arranged on the bottom surface 356B. The dies 362 may be interconnected with the DC+ bus bar 352 via copper ribbon bonds 370, as shown in FIG. 21B. The DC+ bus bar 352 may include extended surfaces 352E that extend away from the bottom surface 352B of the bus bar 352. As shown in FIG. 20, the DC− bus bar 354 is arranged below the DC+ bus bar 352 and the output bus bar 356, and is formed to be much thinner than the bus bars 352, 356, and can include end flanges 354A for supporting the DC− bus bar 354 on platforms 332D of the bottom lid 330. By reducing the size of the DC− bus bar 354, the larger DC+ bus bar 352 and output bus bar 356, which experience the majority of heat losses in the module assembly 310, can be exposed directly to the coolant 398, 399.

The bus bar assembly 350 further includes bus bar extensions 353, 355, 357 that extend out of the main frame body 336 and are configured to be electrically connected to external terminals, as shown in detail in FIG. 20. Each bus bar extension 353, 355, 357 includes an end tab 353A, 355A, 357A and an extension rod 353B, 355B, 357B extending from the end tab 353A, 355A, 357A, the end of the extension rod 353B, 355B, 357B opposite the end tab 353A, 355A, 357A being a threaded end 353C, 355C, 357C.

Each bus bar extension 353, 355, 357 is coupled to a respective bus bar 352, 354, 356 by screwing the threaded end 353C, 355C, 357C into a corresponding threaded bores 352C, 354C, 356C formed in the bus bar 352, 354, 356, as shown in FIGS. 20-21B. When assembled, the extension rod 353B, 355B, 357B extends through a corresponding hole 338A, 338B, 338C formed in the wall 336W of the main frame body 336. Standard O-ring seals (not shown) may be arranged in the holes 338A, 338B, 338C to hermetically seal the bus bar assembly 350 from the outside environment.

As shown in FIG. 20, the main frame body 336 further includes a first tab cover 342 that surrounds the output bus bar end tab 357A on a first tab cover ledge 342A formed within the tab cover 342. The main frame body 336 also includes a second tab cover 346 that surrounds the DC+ and DC− bus bar end tabs 353A, 355A. A second tab cover ledge 346A formed within the tab cover 346 extends between the DC+ and DC− bus bar end tabs 353A, 355A. This second tab cover ledge 346A can provide insulation between the DC+ and DC− bus bar end tabs 353A, 355A.

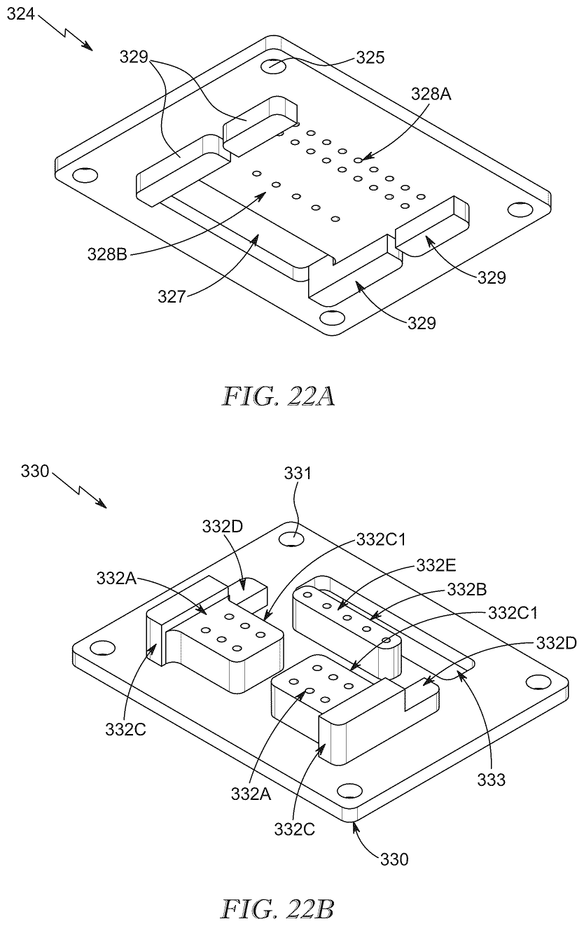

As shown in FIGS. 22A and 22B, the top and bottom lids 324, 330 can be formed to include jet orifices 328A, 328B, 332A, 332B similar to the jet orifices of the other embodiments described herein. In particular, the top lid 324 may be formed as a planar plate that includes jet orifices 328A, 328B formed therethrough, as well as a first vapor outlet 327. A first plurality of jet orifices 328A align with the extended surfaces 392E of the output bus bar 356, and a second plurality of jet orifices 328B are spaced apart from the first plurality of jet orifices 328A and align with the extended surfaces 390E of the first plurality of dies 360. The top lid 324 may further include multiple bus bar retention platforms 329 configured to contact and secure the bus bars 352, 356 in a fixed position within the main frame body 336.

Similar to the top lid 324, the bottom lid 330 may be formed as a planar plate that includes jet orifices 332A, 332B formed therethrough, as well as a second vapor outlet 333. The bottom lid 330 includes two first bus bar retention platforms 332C that are generally aligned with the DC+ bus bar 352 such that the DC+ bus bar 352 can rest on and be secured by the platforms 332C. Each platform 332C can include some of the jet orifices 332A, which align with the extended surfaces 352E of the DC+ bus bar 352. Additional platforms 332D may extend away from the first bus bar retention platforms 332C and can support the DC− bus bar 354 thereon, as described above.

The bottom lid 330 further includes a second bus bar retention platform 332E spaced apart from the two first bus bar retention platforms 332C, as shown in FIG. 22B. The second plurality of jet orifices 332B are arranged on the second bus bar retention platform 332E and align with the extended surfaces 356E of the second plurality of dies 362 arranged on the bottom surface 356B of the output bus bar 356.

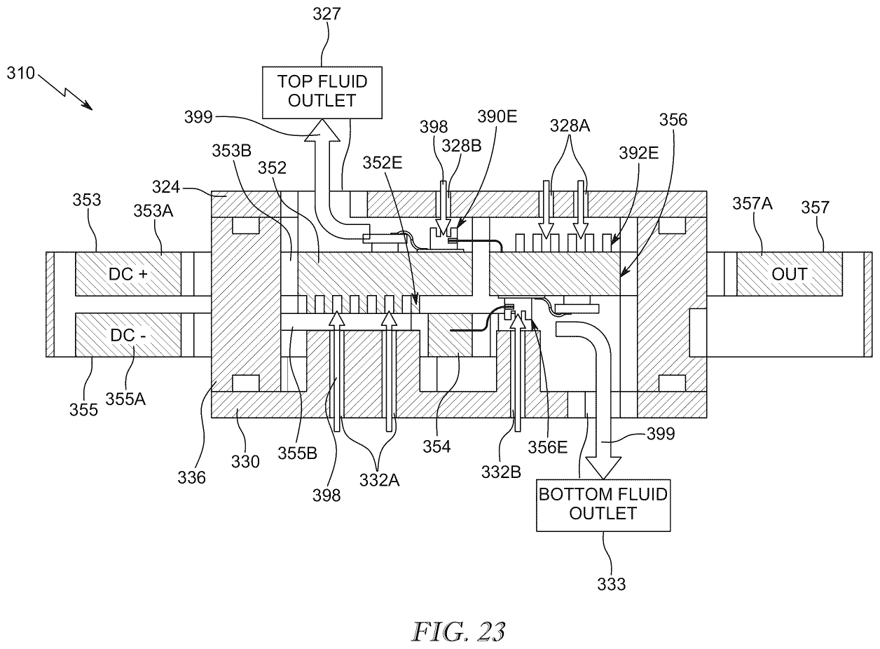

In some embodiments, the power module assembly 310 may be assembled by placing the DC+ and output bus bars 352, 356 into the main frame body 336 before the corresponding bus bar extensions 353, 357 are inserted into the holes 338A, 338B and threaded to the bus bars 352, 356. The partially assembled module assembly 310 is then be inverted and the DC− bus bar 354 is placed into the main frame body 336. The locating features machined into the bottom lid 330, such as the platforms 332C, 332D, 332E, allow the DC− bus bar 354 to slide along the length of the module assembly 310, providing clearance for the DC− bus bar extension 355 to be threaded into the bus bar 354 before sliding into its final position. The platforms 329, 332C, 332D, 332E machined into the top and bottom lids 324, 330 provide additional bus bar 352, 354, 356 retention once die bonding is complete. As can be seen in FIG. 23, the power module assembly 310 operates similar to the power module assembly 10, with inlet coolant 398 flowing from an external source to the jet orifices 328A, 328B, 332A, 332B and then onto a corresponding electrical component of the bus bar assembly 350, and then out of the power module assembly 310 via the vapor outlets 327, 333.

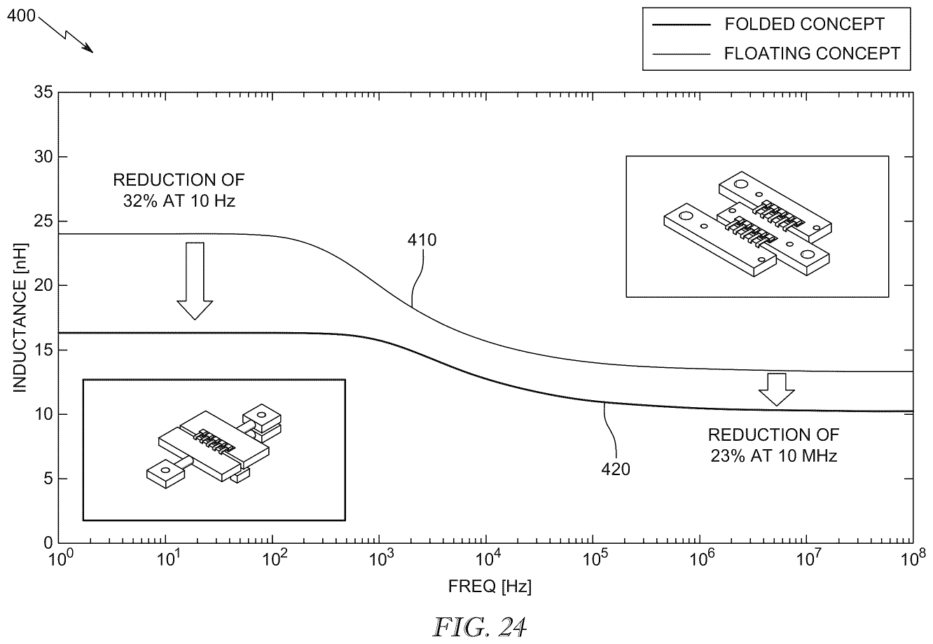

FIG. 24 shows a comparison of finite element analysis results of parasitic inductance for the bus bar assembly shown in FIGS. 9-18 (“floating bus power module”) and the bus bar assembly shown in FIGS. 19A-23 (“folded bus bar configuration”). This analysis was carried out using Ansys Q3D software. The CAD models for each concept were imported into Ansys and appropriately de-featured to retain the critical features of the geometry while improving simulation speed. Both modules were configured with all MOSFET dies in the conducting state, and the impedance was evaluated from the DC+ terminal to the DC− terminal. The resulting FEA-predicted impedance data was used to generate a plot of commutation inductance over frequency for each module concept. Commutation inductance is widely considered to be the most important parasitic figure of merit for WBG-based power modules.

A summary of the results 400 of this analysis is presented in FIG. 24. As expected, the floating bus-bar concept (line 410) demonstrates higher commutation inductance than the folded bus-bar concept (line 420) across the entire frequency range considered in this study (1 Hz-100 MHz). The inductance trend over frequency for both designs correspond to the expected profile for this type of structure, with two regions of relatively constant inductance separated by a transition region in the high kHz range [1]. At low frequency, the folded bus-bar concept achieves a reduction of approximately 32% in commutation inductance relative to the floating bus-bar concept (16.3 nH vs. 24.0 nH). At high-frequency, the folded bus-bar concept achieves a reduction of approximately 23% in commutation inductance relative to the floating bus-bar concept (10.3 nH vs. 13.4 nH). This reduction is expected to yield at least some benefit in terms of switching performance.

Electric power modules should be cooled to function properly. In power electronic architectures where electrically conductive fluids are used as the coolant medium, voltage standoff requirements between the die, bus bars, and eventual coolant medium should be established.

In comparative module architectures, this is accomplished using the expensive direct bond copper (DBC) material processing approach, which grows copper on a ceramic substrate providing an electrically conductive pathway with the necessary voltage standoff between internal electrical component and external cooling. Dies are soldered to the DBC layer which are then attached to a copper baseplate to improve heat transfer. These multiple interface layers increase thermal resistance between the semiconductor die and cooling medium and result in increased electrical losses due to limitations in growth size of the copper layer.

If, instead, a dielectric fluid is used as the coolant medium, the need for voltage isolation between the internal electrical components and the coolant medium is eliminated. This may be used in cases where the heat sink is integral to the current carrying path, such as in press-pack packaging. By using dielectric coolants in comparative module architectures, several layers within the module can be removed, including the ceramic insulator, the baseplate, and the associated solder interfaces between these layers. This results in a significant reduction of thermal impedance between the die junction and the coolant medium. In addition, because a DBC layer is no longer used, the thickness of the copper layers which the dies are attached to are not restricted by the DBC manufacturing process. Thicker copper layers reduce electrical resistance, maintain heat spreading from the dies, and increase thermal mass for transient thermal events. In comparative module architectures, the DBC layer is one of the most expensive components, comprising up to 20% of the total module cost, and its elimination is therefore also attractive from a cost reduction standpoint.

The following numbered clauses include embodiments that are contemplated and non-limiting:

Clause 1. A power module assembly, comprising a frame assembly including an upper frame body and a lower frame body coupled to the upper frame body, at least one of the upper and lower frame bodies including at least one first jet orifice formed therethrough, the at least one first jet orifice configured to receive coolant at a first end of the at least one first jet orifice and discharge the coolant at a second end opposite the first end, the upper and lower frame bodies at least partially defining a chamber therebetween.

Clause 2. The power module assembly of clause 1, any other clause, or combination of clauses, further comprising a bus bar assembly arranged in the chamber and including a first bus bar arranged adjacent to the second end of the at least one first jet orifice.

Clause 3. The power module assembly of clause 1, any other clause, or combination of clauses, wherein the at least one first jet orifice is configured to discharge the coolant directly onto the first bus bar so as to reduce an operating temperature of the first bus bar.

Clause 4. The power module assembly of clause 1, any other clause, or combination of clauses, wherein the first bus bar extends at least partially away from the chamber and is exposed to an outside environment such that at least a portion of the first bus bar is configured to electrically connect to an external electronic device.

Clause 5. The power module assembly of clause 4, any other clause, or combination of clauses, wherein the at least one of the upper and lower frame bodies including at least one first jet orifice further includes a first vapor outlet formed as an opening therein.

Clause 6. The power module assembly of clause 5, any other clause, or combination of clauses, wherein a first portion of the coolant is configured to flow from the at least one first jet orifice, over and around the first bus bar, transfer heat from the first bus bar to the coolant, and subsequently flow away from the first bus bar and the at least one of the upper and lower frame bodies via the first vapor outlet.

Clause 7. The power module assembly of clause 6, any other clause, or combination of clauses, wherein the at least one of the upper and lower frame bodies including at least one first jet orifice is the upper frame body.

Clause 8. The power module assembly of clause 7, any other clause, or combination of clauses, wherein the lower frame body includes at least one second jet orifice configured to receive the coolant at a first end of the at least one second jet orifice and discharge the coolant at a second end opposite the first end.

Clause 9. The power module assembly of clause 8, any other clause, or combination of clauses, wherein the first bus bar is arranged adjacent to the second end of the at least one second jet orifice.

Clause 10. The power module assembly of clause 9, any other clause, or combination of clauses, wherein the at least one second jet orifice is configured to discharge the coolant directly onto the first bus bar at a second location different than a first location at which the at least one first jet orifice is configured to discharge the coolant.

Clause 11. The power module assembly of clause 8, any other clause, or combination of clauses, wherein the bus bar assembly further includes a second bus bar arranged adjacent to the first bus bar.

Clause 12. The power module assembly of clause 11, any other clause, or combination of clauses, wherein the at least one second jet orifice is configured to discharge the coolant directly onto the second bus bar so as to reduce an operating temperature of the second bus bar.

Clause 13. The power module assembly of clause 12, any other clause, or combination of clauses, wherein the second bus bar extends at least partially away from the chamber and is exposed to an outside environment such that at least a portion of the second bus bar is configured to electrically connect to an external electronic device.

Clause 14. The power module assembly of clause 8, any other clause, or combination of clauses, wherein the lower frame body further includes a second vapor outlet.

Clause 15. The power module assembly of clause 14, any other clause, or combination of clauses, wherein a second portion of the coolant is configured to flow from the at least one second jet orifice, over and around the first bus bar, transfer heat from the first bus bar to the coolant, and subsequently flow away from the first bus bar and the lower frame body via the second vapor outlet.

Clause 16. The power module assembly of clause 4, any other clause, or combination of clauses, wherein the bus bar assembly further includes a second bus bar arranged adjacent to the first bus bar.

Clause 17. The power module assembly of clause 16, any other clause, or combination of clauses, wherein the first bus bar is a DC+ bus bar and the second bus bar is an output bus bar.

Clause 18. The power module assembly of clause 17, any other clause, or combination of clauses, wherein the DC+ bus bar includes a first plurality of dies arranged on an upper surface of the DC+ bus bar.

Clause 19. The power module assembly of clause 18, any other clause, or combination of clauses, wherein the output bus bar includes a second plurality of dies arranged on an upper surface of the output bus bar.

Clause 20. The power module assembly of clause 19, any other clause, or combination of clauses, wherein the bus bar assembly further includes at least one first electrical connector connecting the first plurality of dies to the output bus bar.

Clause 21. The power module assembly of clause 20, any other clause, or combination of clauses, wherein the at least one first electrical connector is one of a wire bond or a ribbon bond.

Clause 22. The power module assembly of clause 20, any other clause, or combination of clauses, wherein the bus bar assembly further includes a third bus bar arranged adjacent to the output bus bar such that the output bus bar is arranged between the DC+ bus bar and the third bus bar.

Clause 23. The power module assembly of clause 22, any other clause, or combination of clauses, wherein the third bus bar is a DC− bus bar, and wherein the bus bar assembly further includes at least one second electrical connector connecting the second plurality of dies to the DC− bus bar.

Clause 24. The power module assembly of clause 23, any other clause, or combination of clauses, wherein the at least one second electrical connector is one of a wire bond or a ribbon bond.

Clause 25. The power module assembly of clause 24, any other clause, or combination of clauses, wherein a slot is formed in an upper surface of the DC− bus bar, and wherein a terminal end of the at least one second electrical connector is arranged in the slot.

Clause 26. The power module assembly of clause 4, any other clause, or combination of clauses, wherein at least one of an upper surface of the first bus bar or a lower surface of the first bus bar opposite the upper surface is arranged adjacent to and faces the second end of the at least one first jet orifice.

Clause 27. The power module assembly of clause 26, any other clause, or combination of clauses, wherein the at least one of an upper surface or the lower surface includes at least one surface enhancement including one or more of extended surfaces, porous coatings, or increased surface roughness in order to increase heat transfer efficiency between the coolant and the first bus bar.

Clause 28. The power module assembly of clause 18, any other clause, or combination of clauses, wherein the bus bar assembly further includes at least one thermally conductive block arranged above and soldered to at least one die of the first plurality of dies that is configured increase heat transfer efficiency between the coolant and the first bus bar and increase heat spreading.

Clause 29. The power module assembly of clause 28, any other clause, or combination of clauses, wherein the at least one thermally conductive block is soldered to a source pad of the at least one die.

Clause 30. The power module assembly of clause 29, any other clause, or combination of clauses, wherein first bus bar is comprised of copper.

Clause 31. The power module assembly of clause 30, any other clause, or combination of clauses, wherein the at least one thermally conductive block is comprised of copper.

Clause 32. The power module assembly of clause 28, any other clause, or combination of clauses, wherein the at least one thermally conductive block includes a plurality of thermally conductive blocks.

Clause 33. The power module assembly of clause 32, any other clause, or combination of clauses, wherein each thermally conductive block of the plurality of thermally conductive blocks is arranged above and is soldered to a corresponding die of the first plurality of dies.

Clause 34. The power module assembly of clause 28, any other clause, or combination of clauses, wherein the at least one thermally conductive block includes a single thermally conductive blocks.

Clause 35. The power module assembly of clause 34, any other clause, or combination of clauses, wherein the single thermally conductive block extends across all dies of the first plurality of dies.

Clause 36. The power module assembly of clause 28, any other clause, or combination of clauses, wherein the at least one thermally conductive block includes at least one surface enhancement including one or more of extended surfaces, porous coatings, or increased surface roughness in order to increase heat transfer efficiency between the coolant and the first bus bar.

Clause 37. The power module assembly of clause 6, any other clause, or combination of clauses, wherein the lower frame body includes a bottom surface and bottom walls extending around a perimeter of the bottom surface.

Clause 38. The power module assembly of clause 37, any other clause, or combination of clauses, wherein the upper frame body includes an upper surface and upper walls extending around a perimeter of the upper surface.

Clause 39. The power module assembly of clause 38, any other clause, or combination of clauses, wherein the upper walls, the upper surface, the bottom walls, and the bottom surface define the chamber within which the bus bar assembly is arranged.

Clause 40. The power module assembly of clause 39, any other clause, or combination of clauses, wherein the at least one first jet orifice and the first vapor outlet extend through the upper surface.

Clause 41. The power module assembly of clause 40, any other clause, or combination of clauses, wherein the bus bar assembly further includes a second bus bar arranged adjacent to the first bus bar.

Clause 42. The power module assembly of clause 41, any other clause, or combination of clauses, wherein the lower frame body includes a first notch formed in a first wall of the bottom walls configured to receive the first bus bar and a second notch formed in a second wall of the bottom walls opposite the first wall and configured to receive the second bus bar.

Clause 43. The power module assembly of clause 42, any other clause, or combination of clauses, wherein the upper frame body includes a third notch formed in a third wall of the upper walls aligned with the first notch so as to form a first bus bar opening in the frame assembly and configured to receive the first bus bar and a fourth notch formed in a fourth wall of the upper walls opposite the third wall, the fourth notch aligned with the second notch so as to form a second bus bar opening in the frame assembly, and configured to receive the second bus bar.

Clause 44. The power module assembly of clause 43, any other clause, or combination of clauses, wherein a first insulating flange is arranged within the first bus bar opening so as to insulate the first bus bar from the upper and lower frame bodies.

Clause 45. The power module assembly of clause 44, any other clause, or combination of clauses, wherein a second insulating flange is arranged within the second bus bar opening so as to insulate the second bus bar from the upper and lower frame bodies.

Clause 46. A power module assembly, comprising a frame assembly including a first frame body including a first jet orifice formed therethrough and a second frame body coupled to the first frame body.

Clause 47. The power module assembly of clause 46, any other clause, or combination of clauses, further comprising a bus bar assembly arranged at least partially within the second frame body and including a first bus bar arranged adjacent to an outlet of the first jet orifice.

Clause 48. The power module assembly of clause 47, any other clause, or combination of clauses, wherein the first jet orifice is configured to discharge coolant from the outlet directly onto the first bus bar so as to reduce an operating temperature of the first bus bar.

Clause 49. The power module assembly of clause 48, any other clause, or combination of clauses, wherein the first bus bar extends at least partially away from the second frame body and is exposed to an outside environment such that at least a portion of the first bus bar is configured to electrically connect to an external electronic device.

Clause 50. The power module assembly of clause 49, any other clause, or combination of clauses, wherein the bus bar assembly further includes a second bus bar arranged adjacent to the first bus bar.

Clause 51. The power module assembly of clause 50, any other clause, or combination of clauses, wherein the first bus bar is a DC+ bus bar and the second bus bar is an output bus bar.

Clause 52. The power module assembly of clause 51, any other clause, or combination of clauses, wherein the DC+ bus bar includes a first plurality of dies arranged on an upper surface of the DC+ bus bar.

Clause 53. The power module assembly of clause 52, any other clause, or combination of clauses, wherein the output bus bar includes a second plurality of dies arranged on an upper surface of the output bus bar.

Clause 54. The power module assembly of clause 53, any other clause, or combination of clauses, wherein the bus bar assembly further includes at least one first electrical connector connecting the first plurality of dies to the output bus bar.

Clause 55. The power module assembly of clause 54, any other clause, or combination of clauses, wherein the at least one first electrical connector is one of a wire bond or a ribbon bond.

Clause 56. The power module assembly of clause 54, any other clause, or combination of clauses, wherein the bus bar assembly further includes a third bus bar arranged adjacent to the output bus bar such that the output bus bar is arranged between the DC+ bus bar and the third bus bar.

Clause 57. The power module assembly of clause 56, any other clause, or combination of clauses, wherein the third bus bar is a DC− bus bar.

Clause 58. The power module assembly of clause 57, any other clause, or combination of clauses, wherein the bus bar assembly further includes at least one second electrical connector connecting the second plurality of dies to the DC− bus bar.

Clause 59. The power module assembly of clause 58, any other clause, or combination of clauses, wherein the at least one second electrical connector is one of a wire bond or a ribbon bond.

Clause 60. The power module assembly of clause 59, any other clause, or combination of clauses, wherein the at least one second electrical connector is one of a wire bond or a ribbon bond.

Clause 61. The power module assembly of clause 60, any other clause, or combination of clauses, wherein a slot is formed in an upper surface of the DC− bus bar.

Clause 62. The power module assembly of clause 61, any other clause, or combination of clauses, wherein a terminal end of the at least one second electrical connector is arranged in the slot.

Clause 63. The power module assembly of clause 48, any other clause, or combination of clauses, wherein the second frame body defines a large opening within which the bus bar assembly is housed.

Clause 64. The power module assembly of clause 63, any other clause, or combination of clauses, wherein the frame assembly further includes a third frame body.

Clause 65. The power module assembly of clause 64, any other clause, or combination of clauses, wherein the first frame body and the third frame body are arranged on opposing sides of the second frame body so as to enclose the large opening and define a chamber therewithin.

Clause 66. The power module assembly of clause 63, any other clause, or combination of clauses, wherein the first bus bar is arranged entirely within the large opening.

Clause 67. The power module assembly of clause 66, any other clause, or combination of clauses, wherein the bus bar assembly further includes a second bus bar arranged adjacent to the first bus bar and arranged entirely within the large opening.

Clause 68. The power module assembly of clause 67, any other clause, or combination of clauses, wherein the bus bar assembly further includes a first bus bar extension coupled to and extending away from the first bus bar and a second bus bar extension coupled to and extending away from the second bus bar.

Clause 69. The power module assembly of clause 68, any other clause, or combination of clauses, wherein at least a portion of the first bus bar extension extends through a first wall of the second frame body.

Clause 70. The power module assembly of clause 69, any other clause, or combination of clauses, wherein at least a portion of the second bus bar extension extends through a second wall of the second frame body opposite the first wall.

Clause 71. The power module assembly of clause 70, any other clause, or combination of clauses, wherein a longitudinal extent of each of the first and second bus bars extends perpendicular to a longitudinal extent of each of the first and second bus bar extensions.

Clause 72. The power module assembly of clause 70, any other clause, or combination of clauses, wherein the at least a portion of the first and second bus bar extensions are threadably engaged with corresponding threaded bores formed in the first and second bus bars, respectively.

Clause 73. A method comprises coupling a lower frame body to an upper frame body to form a frame assembly, the upper and lower frame bodies at least partially defining a chamber therebetween.

Clause 74. The method of clause 73, any other clause, or combination of clauses, further comprising forming at least one first jet orifice through at least one of the upper and lower frame bodies.

Clause 75. The method of clause 74, any other clause, or combination of clauses, further comprising directing coolant to a first end of the at least one first jet orifice.

Clause 76. The method of clause 75, any other clause, or combination of clauses, further comprising arranging a bus bar assembly in the chamber, the bus bar assembly including a first bus bar arranged adjacent to a second end of the at least one first jet orifice opposite the first end.

Clause 77. The method of clause 76, any other clause, or combination of clauses, further comprising discharging the coolant at the second end of the at least one first jet orifice directly onto the first bus bar so as to reduce an operating temperature of the first bus bar.

Clause 78. The method of clause 77, any other clause, or combination of clauses, wherein the first bus bar extends at least partially away from the chamber and is exposed to an outside environment such that at least a portion of the first bus bar is configured to electrically connect to an external electronic device.

Clause 79. The method of clause 78, any other clause, or combination of clauses, further comprising directing a first portion of the coolant from the at least one first jet orifice over and around the first bus bar.

Clause 80. The method of clause 79, any other clause, or combination of clauses, further comprising transferring heat from the first bus bar to the coolant.

Clause 81. The method of clause 80, any other clause, or combination of clauses, subsequently directing the coolant away from the first bus bar and at least one of the upper and lower frame bodies via a first vapor outlet formed in the at least one of the upper and lower frame bodies.

Clause 82. The method of clause 81, any other clause, or combination of clauses, wherein the at least one of the upper and lower frame bodies including at least one first jet orifice is the upper frame body.

Clause 83. The method of clause 82, any other clause, or combination of clauses, wherein the lower frame body includes at least one second jet orifice configured to receive the coolant at a first end of the at least one second jet orifice and discharge the coolant at a second end opposite the first end.

Clause 84. The method of clause 83, any other clause, or combination of clauses, wherein the first bus bar is arranged adjacent to the second end of the at least one second jet orifice.

Clause 85. The method of clause 84, any other clause, or combination of clauses, further comprising discharging, via the at least one second jet orifice, the coolant directly onto the first bus bar at a second location different than a first location at which the at least one first jet orifice is configured to discharge the coolant.

Clause 86. The method of clause 83, any other clause, or combination of clauses, wherein the bus bar assembly further includes a second bus bar arranged adjacent to the first bus bar.

Clause 87. The method of clause 86, any other clause, or combination of clauses, further comprising discharging, via the at least one second jet orifice, the coolant directly onto the second bus bar so as to reduce an operating temperature of the second bus bar.

1. A power module assembly, comprising
a frame assembly including an upper frame body and a lower frame body coupled to the upper frame body, at least one of the upper and lower frame bodies including at least one first jet orifice formed therethrough, the at least one first jet orifice configured to receive coolant at a first end of the at least one first jet orifice and discharge the coolant at a second end opposite the first end, the upper and lower frame bodies at least partially defining a chamber therebetween, and
a bus bar assembly arranged in the chamber and including a first bus bar arranged adjacent to the second end of the at least one first jet orifice,
wherein the at least one first jet orifice is configured to discharge the coolant directly onto the first bus bar so as to reduce an operating temperature of the first bus bar.

2. The power module assembly of claim 1, wherein the first bus bar extends at least partially away from the chamber and is exposed to an outside environment such that at least a portion of the first bus bar is configured to electrically connect to an external electronic device.

3. The power module assembly of claim 2, wherein the at least one of the upper and lower frame bodies including at least one first jet orifice further includes a first vapor outlet formed as an opening therein, and wherein a first portion of the coolant is configured to flow from the at least one first jet orifice, over and around the first bus bar, transfer heat from the first bus bar to the coolant, and subsequently flow away from the first bus bar and the at least one of the upper and lower frame bodies via the first vapor outlet.

4. The power module assembly of claim 3, wherein the at least one of the upper and lower frame bodies including at least one first jet orifice is the upper frame body, and wherein the lower frame body includes at least one second jet orifice configured to receive the coolant at a first end of the at least one second jet orifice and discharge the coolant at a second end opposite the first end.

5. The power module assembly of claim 4, wherein the first bus bar is arranged adjacent to the second end of the at least one second jet orifice, and wherein the at least one second jet orifice is configured to discharge the coolant directly onto the first bus bar at a second location different than a first location at which the at least one first jet orifice is configured to discharge the coolant.

6. The power module assembly of claim 4, wherein the bus bar assembly further includes a second bus bar arranged adjacent to the first bus bar, and wherein the at least one second jet orifice is configured to discharge the coolant directly onto the second bus bar so as to reduce an operating temperature of the second bus bar.

7. The power module assembly of claim 2, wherein the bus bar assembly further includes a second bus bar arranged adjacent to the first bus bar, and wherein the first bus bar is a DC+ bus bar and the second bus bar is an output bus bar, wherein the DC+ bus bar includes a first plurality of dies arranged on an upper surface of the DC+ bus bar, and wherein the bus bar assembly further includes at least one thermally conductive block arranged above and soldered to at least one die of the first plurality of dies that is configured increase heat transfer efficiency between the coolant and the first bus bar and increase heat spreading.

8. The power module assembly of claim 7, wherein the at least one thermally conductive block includes at least one surface enhancement including one or more of extended surfaces, porous coatings, or increased surface roughness in order to increase heat transfer efficiency between the coolant and the first bus bar.

9. The power module assembly of claim 2, wherein at least one of an upper surface of the first bus bar or a lower surface of the first bus bar opposite the upper surface is arranged adjacent to and faces the second end of the at least one first jet orifice, and wherein the at least one of an upper surface or the lower surface includes at least one surface enhancement including one or more of extended surfaces, porous coatings, or increased surface roughness in order to increase heat transfer efficiency between the coolant and the first bus bar.

10. The power module assembly of claim 3, wherein the lower frame body includes a bottom surface and bottom walls extending around a perimeter of the bottom surface.

11. The power module assembly of claim 10, wherein the upper frame body includes an upper surface and upper walls extending around a perimeter of the upper surface, wherein the upper walls, the upper surface, the bottom walls, and the bottom surface define the chamber within which the bus bar assembly is arranged, and wherein the at least one first jet orifice and the first vapor outlet extend through the upper surface.

12. The power module assembly of claim 11, wherein the bus bar assembly further includes a second bus bar arranged adjacent to the first bus bar, wherein the lower frame body includes a first notch formed in a first wall of the bottom walls configured to receive the first bus bar and a second notch formed in a second wall of the bottom walls opposite the first wall and configured to receive the second bus bar, wherein the upper frame body includes a third notch formed in a third wall of the upper walls aligned with the first notch so as to form a first bus bar opening in the frame assembly and configured to receive the first bus bar and a fourth notch formed in a fourth wall of the upper walls opposite the third wall, the fourth notch aligned with the second notch so as to form a second bus bar opening in the frame assembly, and configured to receive the second bus bar.

13. The power module assembly of claim 12, wherein a first insulating flange is arranged within the first bus bar opening so as to insulate the first bus bar from the upper and lower frame bodies, and wherein a second insulating flange is arranged within the second bus bar opening so as to insulate the second bus bar from the upper and lower frame bodies.

14. A power module assembly, comprising
a frame assembly including a first frame body including a first jet orifice formed therethrough and a second frame body coupled to the first frame body; and
a bus bar assembly arranged at least partially within the second frame body and including a first bus bar arranged adjacent to an outlet of the first jet orifice,
wherein the first jet orifice is configured to discharge coolant from the outlet directly onto the first bus bar so as to reduce an operating temperature of the first bus bar.

15. The power module assembly of claim 14, wherein the first bus bar extends at least partially away from the second frame body and is exposed to an outside environment such that at least a portion of the first bus bar is configured to electrically connect to an external electronic device.

16. The power module assembly of claim 14, wherein the second frame body defines a large opening within which the bus bar assembly is housed.

17. The power module assembly of claim 16, wherein the frame assembly further includes a third frame body, and wherein the first frame body and the third frame body are arranged on opposing sides of the second frame body so as to enclose the large opening and define a chamber therewithin.

18. The power module assembly of claim 16, wherein the first bus bar is arranged entirely within the large opening, and wherein the bus bar assembly further includes a second bus bar arranged adjacent to the first bus bar and arranged entirely within the large opening, and wherein the bus bar assembly further includes a first bus bar extension coupled to and extending away from the first bus bar and a second bus bar extension coupled to and extending away from the second bus bar.

19. The power module assembly of claim 18, wherein at least a portion of the first bus bar extension extends through a first wall of the second frame body, and wherein at least a portion of the second bus bar extension extends through a second wall of the second frame body opposite the first wall.

20. A method, comprising
coupling a lower frame body to an upper frame body to form a frame assembly, the upper and lower frame bodies at least partially defining a chamber therebetween,
forming at least one first jet orifice through at least one of the upper and lower frame bodies,
directing coolant to a first end of the at least one first jet orifice,
arranging a bus bar assembly in the chamber, the bus bar assembly including a first bus bar arranged adjacent to a second end of the at least one first jet orifice opposite the first end, and
discharging the coolant at the second end of the at least one first jet orifice directly onto the first bus bar so as to reduce an operating temperature of the first bus bar.
